(19) United States
(12) Patent Application Publication
(10) Pub. No.: US 2025/0318424 A1
(43) Pub. Date: Oct. 9, 2025

(54) ORGANOMETALLIC COMPLEX AND ORGANIC LIGHT-EMITTING DEVICE

(71) Applicant: CANON KABUSHIKI KAISHA, Tokyo (JP)

(72) Inventors: AKIRA TSUBOYAMA, Tokyo (JP); AKANE TANAKA, Kanagawa (JP)

(21) Appl. No.: 19/243,539

(22) Filed: Jun. 19, 2025

Related U.S. Application Data
(63) Continuation of application No. PCT/JP2023/044214, filed on Dec. 11, 2023.

(30) Foreign Application Priority Data
Dec. 26, 2022 (JP) 2022-208030

(51) Int. Cl. H10K 85/30; B41J 2/45; C09K 11/06; G03G 15/04; H10K 50/12

(52) U.S. Cl. CPC H10K 85/361; C09K 11/06; H10K 85/346; B41J 2/45; C09K 2211/1007; C09K 2211/1011; C09K 2211/1029; C09K 2211/185; G03G 15/04054; H10K 50/12

(57) ABSTRACT

An organometallic complex is represented by general formula (1).

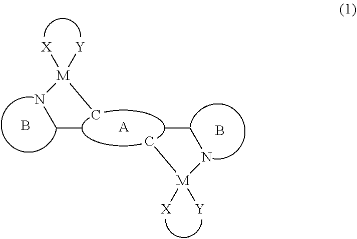

M is Pd or Pt. B-A-B is a tetradentate ligand formed by bonding a ring A to rings B. The ring A is a hydrocarbon aromatic ring or heteroaromatic ring that may have a substituent, and is selected from a benzene ring, etc. The substituent that the ring A may have is selected from a linear or branched C1 to C6 alkyl group, etc. Each of the rings B is a monocyclic heteroaromatic ring that may have a substituent, and is selected from a pyridine ring, etc. The substituent that the ring B may have is selected from a linear or branched C1 to C6 alkyl group, etc. Each X-Y is a bidentate ligand, and atoms bonded to M are selected from C, N, and O atoms. The two bidentate ligands do not bond together.

### CROSS-REFERENCE TO RELATED APPLICATIONS

This application is a Continuation of International Patent Application No. PCT/JP2023/044214, filed Dec. 11, 2023, which claims the benefit of Japanese Patent Application No. 2022-208030, filed Dec. 26, 2022, both of which are hereby incorporated by reference herein in their entirety.

### BACKGROUND

### Field of the Technology

The present disclosure relates to an organometallic complex and an organic light-emitting device using the organometallic complex.

### Description of the Related Art

An organic light-emitting device is an electronic device including a first electrode, a second electrode, and an organic compound layer disposed between the electrodes. The injection of electrons and holes from this pair of electrodes generates excitons of a light-emitting organic compound in the organic compound layer, and the organic light-emitting device emits light when the excitons return to the ground state. Such an organic light-emitting device is also referred to as an organic electroluminescence device or an organic EL device.

Light-emitting materials used for light-emitting compounds can be broadly classified into two types of materials on the basis of their luminescence principle: fluorescent materials and phosphorescent materials. In organic EL devices, phosphorescent materials, which emit light from the triplet excited state, are known to exhibit higher photoluminescence quantum yields than fluorescent materials, which emit light from the singlet excited state. As an example thereof, NPL 1 describes, as a green phosphorescent material, Ir(ppy)₃ which is a metal complex represented by the following structure.

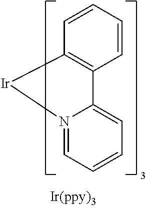

It has been reported that a light-emitting organic EL device including 4,4′-di(N-carbazolyl)biphenyl (CBP) doped with the metal complex Ir(ppy)₃ emits green light having an emission wavelength of 510 nm and has an external quantum efficiency of 13%, which is significantly higher than a quantum efficiency limit value (5%) of an existing light-emitting device utilizing light emission from the singlet excited state.

In addition to Ir complexes, metal complexes with central metals such as platinum (Pt) are being actively developed as phosphorescent materials.

NPL 2 describes an example of a binuclear platinum complex that emits phosphorescence in the infrared region. NPL 3 describes an example of a binuclear platinum complex that emits phosphorescence in the orange-red region. NPL 4 describes an example of a binuclear platinum complex that emits phosphorescence in the green-yellow region. PTL 1 describes an example of a binuclear iridium complex that emits phosphorescence in the red region.

### CITATION LIST

### Patent Literature

PTL 1 Japanese Patent Laid-Open No. 2003-73388

### Non Patent Literature

NPL 1 Appl. Phys. Lett., vol. 75, p. 4, 1999
NPL 2 Organic Electronics, 87, (2020), 105902
NPL 3 Journal of Materials Chemistry C 2021, 9, 9505
NPL 4 Dalton Transactions 2020, 49, 8722-8733

However, the complex described in NPL 2 has problems, such as light emission not lying in the visible light region, which is used in displays and illuminations, and the photoluminescence quantum yield (hereinafter, may be referred to as “PLQY”) being 0.77%, which is a low PLQY for a light-emitting material. The complexes described in NPL 3, NPL 4, and PTL 1 have problems in that, for example, a half-width (full width at half maximum (FWHM)) of an emission spectrum is as wide as 65 nm to 100 nm or more, and thus high color purity is less likely to be achieved.

NPL 2 will be described in more detail. NPL 2 describes the molecular structure and emission characteristics of a binuclear platinum complex (Comparative example compound 03) shown below. Comparative example compound 03 has an emission peak at 730 nm, a half-width of 60 nm, and a PLQY of 0.77%. The emission peak at 730 nm lies in the infrared region. In addition, the half-width is as wide as 60 nm. The PLQY is 1% or less, and highly efficient light emission cannot be expected in an organic light-emitting device that uses this material as a light-emitting dopant. Accordingly, the problems of the material disclosed in NPL 2 lie in that light emission is in the infrared region, high color purity cannot be achieved due to a wide half-width, and the PLQY is low.

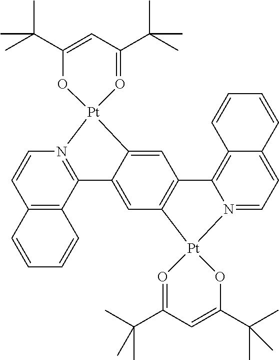

Comparative example compound 03

### SUMMARY

The present disclosure has been made in view of the above problems. The present disclosure is directed to provide a light-emitting material that is stable and that can achieve high efficiency and high color purity.

An organometallic complex according to the present disclosure is represented by general formula (1).

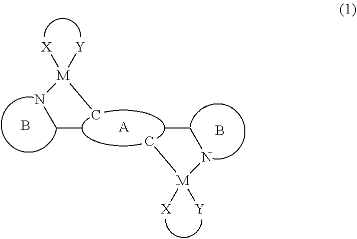

In general formula (1), M is Pd or Pt; B-A-B is a tetradentate ligand formed by bonding a ring A and rings B together; the ring A is a hydrocarbon aromatic ring or a heteroaromatic ring that may have a substituent, and is selected from a benzene ring, a fluorene ring, a phenanthrene ring, a pyrene ring, a triphenylene ring, a carbazole ring, an N-phenylcarbazole ring, a dibenzofuran ring, a dibenzothiophene ring, a dibenzothiophene 5,5-dioxide ring, a pyridine ring, and a pyrazine ring; the substituent that the ring A may have is selected from a linear or branched alkyl group having 1 to 6 carbon atoms, a fluorine group, a triphenylsilyl group, and a perfluoroalkyl group; each of the rings B is a monocyclic heteroaromatic ring that may have a substituent, and is selected from a pyridine ring, a pyrazine ring, a pyrimidine ring, a pyrrole ring, a pyrazole ring, and a triazole ring; the substituent that the ring B may have is selected from a linear or branched alkyl group having 1 to 6 carbon atoms, a fluorine group, a triphenylsilyl group, a perfluoroalkyl group, an aryl group, and a heteroaryl group; each X—Y is a bidentate ligand, and atoms bonded to M are selected from a C atom, a N atom, and an O atom; and the two bidentate ligands do not bond together.

Features of the present disclosure will become apparent from the following description of exemplary embodiments with reference to the attached drawings.

### BRIEF DESCRIPTION OF THE DRAWINGS

FIG. 1A is a schematic sectional view illustrating an example of a pixel of a display apparatus according to an embodiment of the present disclosure.

FIG. 1B is a schematic sectional view illustrating an example of a display apparatus using an organic light-emitting device according to an embodiment of the present disclosure.

FIG. 2 is a schematic view illustrating an example of a display apparatus according to an embodiment of the present disclosure.

FIG. 3A is a schematic view illustrating an example of an imaging apparatus according to an embodiment of the present disclosure.

FIG. 3B is a schematic view illustrating an example of an electronic apparatus according to an embodiment of the present disclosure.

FIG. 4A is a schematic view illustrating an example of a display apparatus according to an embodiment of the present disclosure.

FIG. 4B is a schematic view illustrating an example of a foldable display apparatus.

FIG. 5A is a schematic view illustrating an example of an illumination apparatus according to an embodiment of the present disclosure.

FIG. 5B is a schematic view illustrating an example of a moving object including a vehicle lighting fixture according to an embodiment of the present disclosure.

FIG. 6A is a schematic view illustrating an example of a wearable device according to an embodiment of the present disclosure.

FIG. 6B is a schematic view illustrating another example of the wearable device according to an embodiment of the present disclosure.

FIG. 7A is a schematic diagram illustrating an example of an image forming apparatus according to an embodiment of the present disclosure.

FIG. 7B is a schematic view illustrating an example of an exposure light source of an image forming apparatus according to an embodiment of the present disclosure.

FIG. 7C is a schematic view illustrating an example of an exposure light source of an image forming apparatus according to an embodiment of the present disclosure.

FIG. 8 includes drawn images of X-ray crystallography of Example compound 01.

FIG. 9 includes drawn images of X-ray crystallography of Example compound 02.

FIG. 10 is PL emission spectra of Example compound 01 and Comparative example Compound 01.

FIG. 11 is PL emission spectra of Example compound 02 and Comparative example compound 02.

### DESCRIPTION OF THE EMBODIMENTS

Embodiments of the present disclosure will be described below. The present disclosure is not limited to the description below, and a person skilled in the art can easily understand that various modifications in the forms and details can be made without departing from the spirit and the scope of the present disclosure. That is, the present disclosure should not be construed as being limited to the following description.

### Organometallic Complex

In Pt complexes and Pd complexes, the emission spectrum has two peaks and is broad; consequently, the emission spectrum has a large half-width. In the case where the emission spectrum has a large half-width, light emission with high color purity is less likely to be achieved when such a complex is used as a light-emitting dopant of an organic light-emitting device. Therefore, to realize a light-emitting device with high color purity, a complex optical design is required to enhance the color purity. On the other hand, if the half-width of the emission spectrum of the light-emitting dopant is originally small, a light-emitting device having high color purity can be realized without a burden on the device design. Decreasing the half-width of the light-emitting dopant to improve the color purity has been an issue for the development of a light-emitting dopant. The present inventors have conducted extensive studies to address the issue and consequently found an organometallic complex that exhibits an emission spectrum having a small half-width.

An organometallic complex according to the present disclosure is represented by general formula (1) below. In general formula (1), two Ms are located opposite each other with a tetradentate ligand B-A-B therebetween. Alternatively, for example, two Ms may be located on the same side with respect to the tetradentate ligand B-A-B as in Example compound 02 described later.

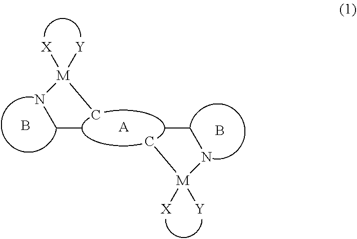

### M

In general formula (1), M is Pd or Pt. In general formula (1), two Ms are the same. To be used as a phosphorescent material, a heavy atom metal is required as the luminescent center, and the heavy-atom effect due to Pt or Pd plays a major role in phosphorescence emission. Since Pt has a larger atomic weight, good properties are often obtained for phosphorescence. Pd emits phosphorescence or delayed fluorescence and thus is useful.

### B-A-B

In general formula (1), B-A-B is a tetradentate ligand formed by bonding a ring A and rings B together. In general formula (1), the two rings B are the same.

### Ring A

The ring A is bonded to M at two C atoms. The ring A is a hydrocarbon aromatic ring or a heteroaromatic ring that may have a substituent, and is selected from a benzene ring, a naphthalene ring, a fluorene ring, a phenanthrene ring, a pyrene ring, a triphenylene ring, a carbazole ring, an N-phenylcarbazole ring, a dibenzofuran ring, a dibenzothiophene ring, a dibenzothiophene 5,5-dioxide ring, a pyridine ring, and a pyrazine ring.

The substituent that the ring A may have is selected from a linear or branched alkyl group having 1 to 6 carbon atoms, a fluorine group, a triphenylsilyl group, and a perfluoroalkyl group.

Specific examples of the linear or branched alkyl group having 1 to 6 carbon atoms include a methyl group, an ethyl group, a n-propyl group, an i-propyl group, a n-butyl group, an i-butyl group, a sec-butyl group, a tert-butyl group, a n-pentyl group, an i-pentyl group, a tert-pentyl group, a neopentyl group, a 3-pentyl group, and a n-hexyl group. Of these, a methyl group is preferred.

### Ring B

Each of the rings B is bonded to M at one N atom. The ring B is a monocyclic heteroaromatic ring that may have a substituent, and is selected from a pyridine ring, a pyrazine ring, a pyrimidine ring, a pyrrole ring, a pyrazole ring, and a triazole ring.

The substituent that the ring B may have is selected from a linear or branched alkyl group having 1 to 6 carbon atoms, a fluorine group, a triphenylsilyl group, a perfluoroalkyl group, an aryl group, and a heteroaryl group.

Examples of the linear or branched alkyl group having 1 to 6 carbon atoms include the groups described in the substituent that the ring A may have. Of these, a methyl group, an i-propyl group, and a tert-butyl group are preferred.

Specific examples of the aryl group include a phenyl group, a trimethylphenyl group, a naphthyl group, a phenanthryl group, an anthryl group, a fluorenyl group, a biphenylenyl group, an acenaphthylenyl group, a chrysenyl group, a pyrenyl group, a triphenylenyl group, a picenyl group, a fluoranthenyl group, a perylenyl group, a naphthacenyl group, a biphenyl group, and a terphenyl group. Of these, a phenyl group, a trimethylphenyl group, and a terphenyl group are preferred.

Specific examples of the heteroaryl group include a thienyl group, a pyrrolyl group, a pyrazinyl group, a pyridyl group, an indolyl group, a quinolyl group, an isoquinolyl group, a naphthyridinyl group, an acridinyl group, a phenanthrolinyl group, a carbazolyl group, a benzo[a]carbazolyl group, a benzo[b]carbazolyl group, a benzo[c]carbazolyl group, a phenazinyl group, a phenoxazinyl group, a phenothiazinyl group, a benzothiophenyl group, a dibenzothiophenyl group, a benzofuranyl group, a dibenzofuranyl group, an oxazolyl group, and an oxadiazolyl group. Of these, a carbazolyl group is preferred.

### X-Y

In general formula (1), X—Y is a bidentate ligand, and atoms bonded to M are selected from a C atom, a N atom, and an O atom. In general formula (1), the two bidentate ligands X-Y are the same.

### Ligands

Non-limiting specific examples of ligands that can be used for the metal complex according to the present embodiment are shown below.

### B-A-B

The tetradentate ligand B-A-B is introduced as a main ligand. The term “main ligand” as used herein refers to a ligand that mainly determines emission characteristics of the metal complex. The tetradentate ligand B-A-B has a developed conjugated system and exhibits light emission in the visible light region when forming a metal complex. Examples of the tetradentate ligand B-A-B include ligands shown below. Each R in ligands L04 and L05 is a linear or branched alkyl group having 1 to 6 carbon atoms.

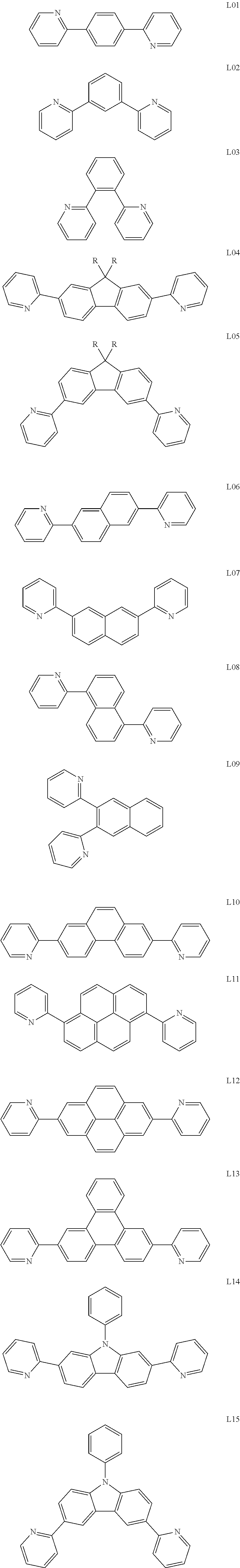

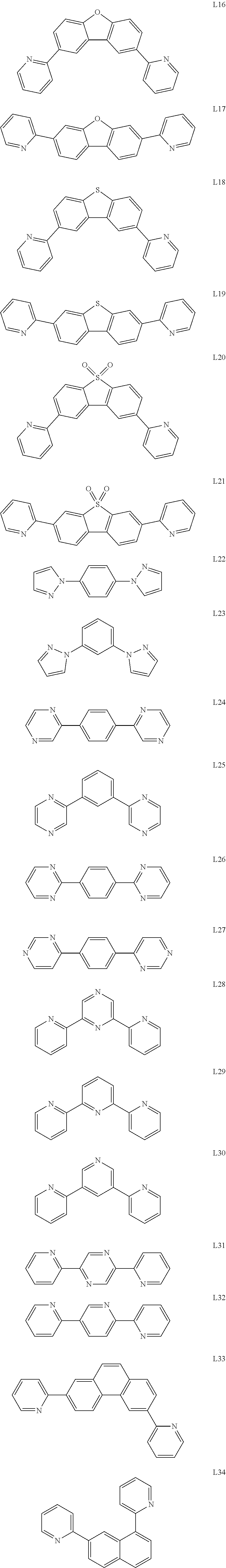

### X-Y

Each of the bidentate ligands X-Y is introduced as an auxiliary ligand. The bidentate ligand X-Y is preferably designed so as not to inhibit light emission involving the main ligand. The use of the bidentate ligand X-Y stabilizes the metal complex. Examples of the bidentate ligand X-Y include ligands shown below. The ligands shown below may have an alkyl group and an aryl group that may have a substituent. Examples of the alkyl group and the aryl group include the groups described in the substituent that the ring A may have and the groups described in the substituent that the ring B may have.

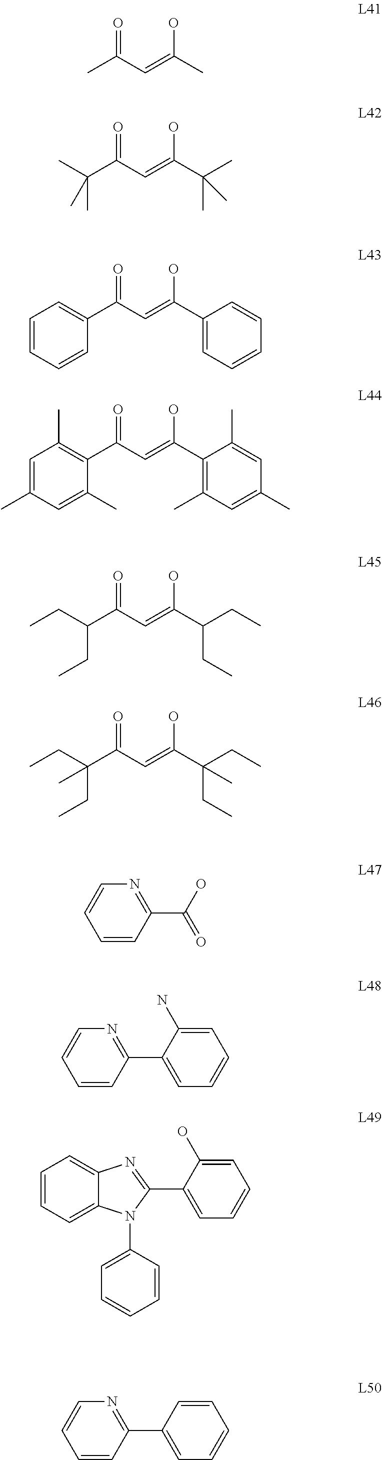

### Specific Examples

Non-limiting specific examples of the metal complex according to the present embodiment are shown below.

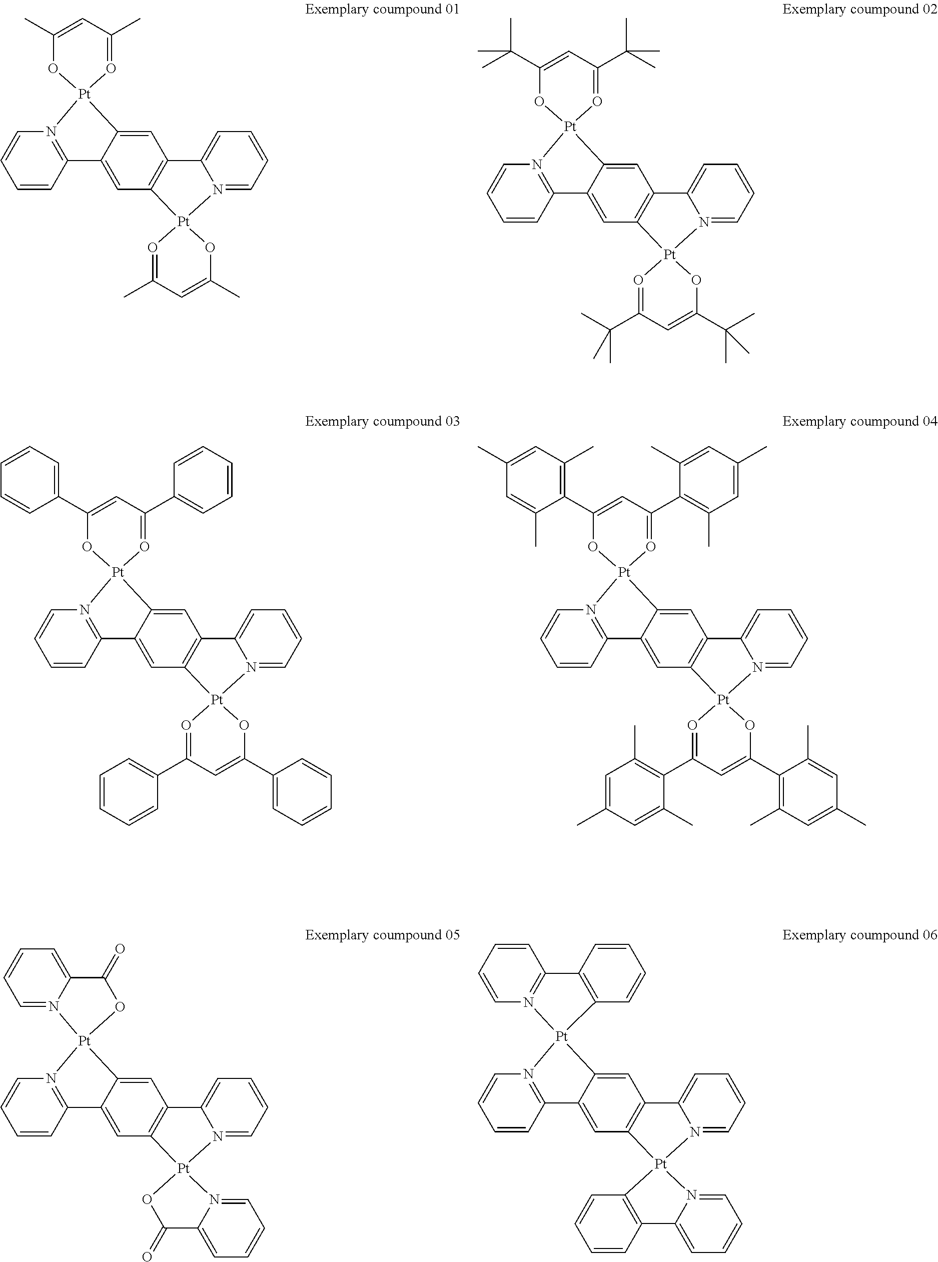

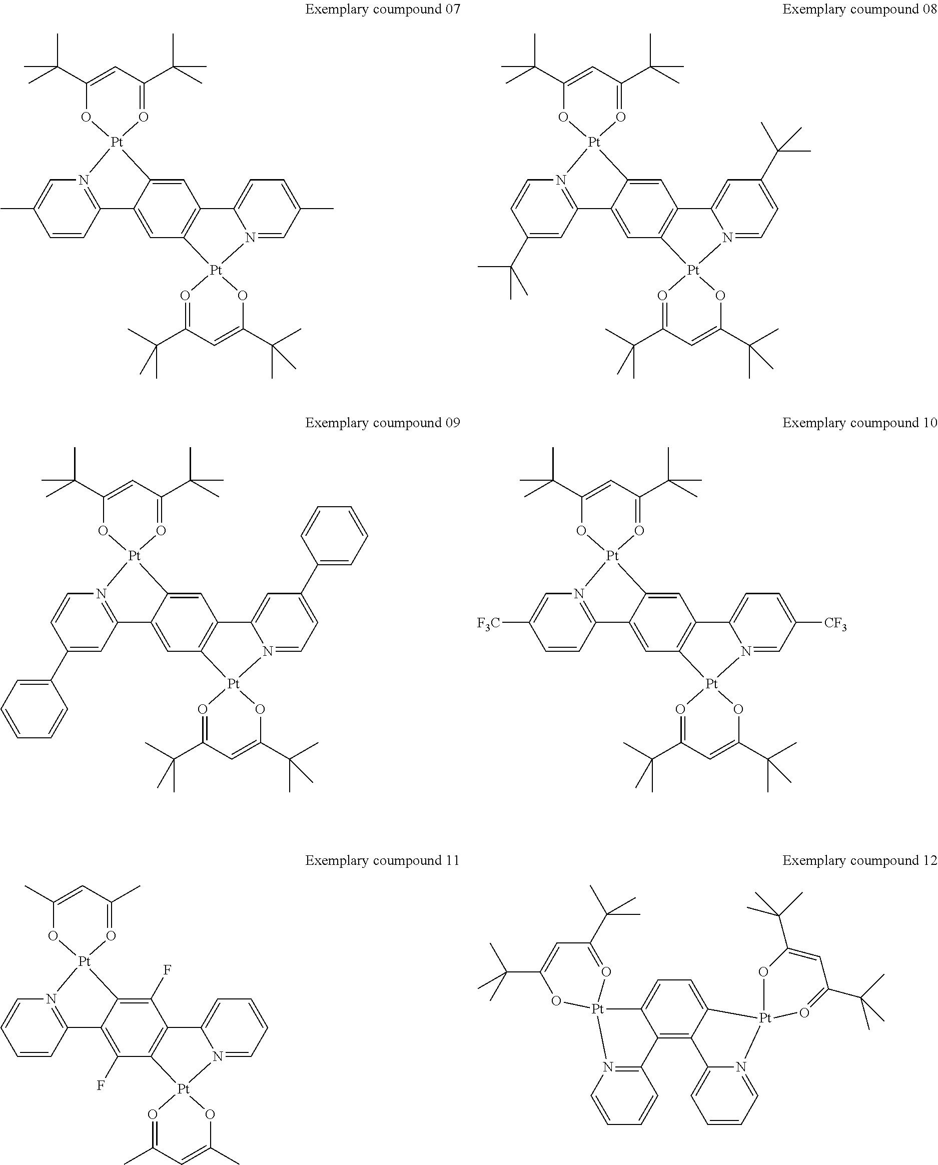

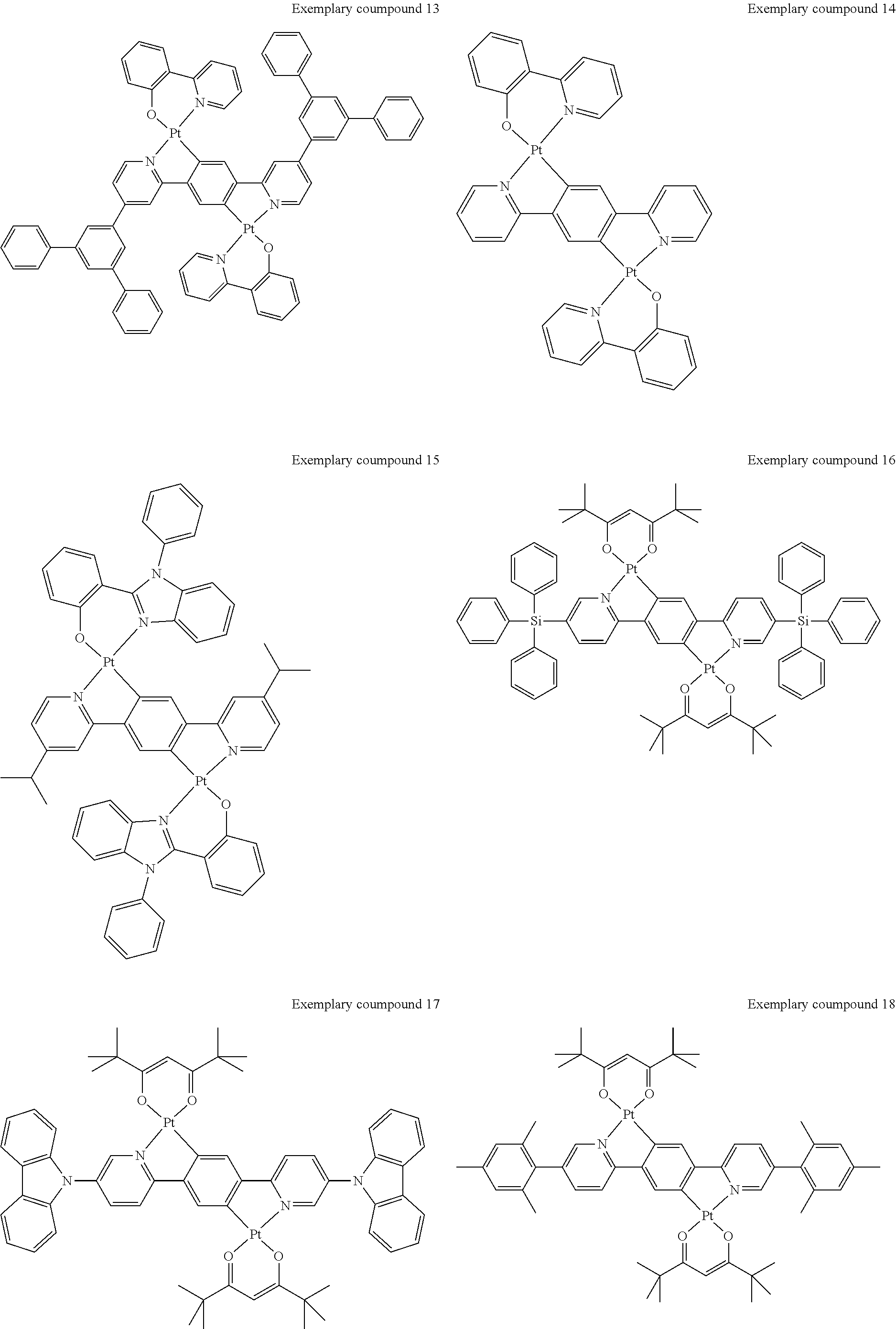

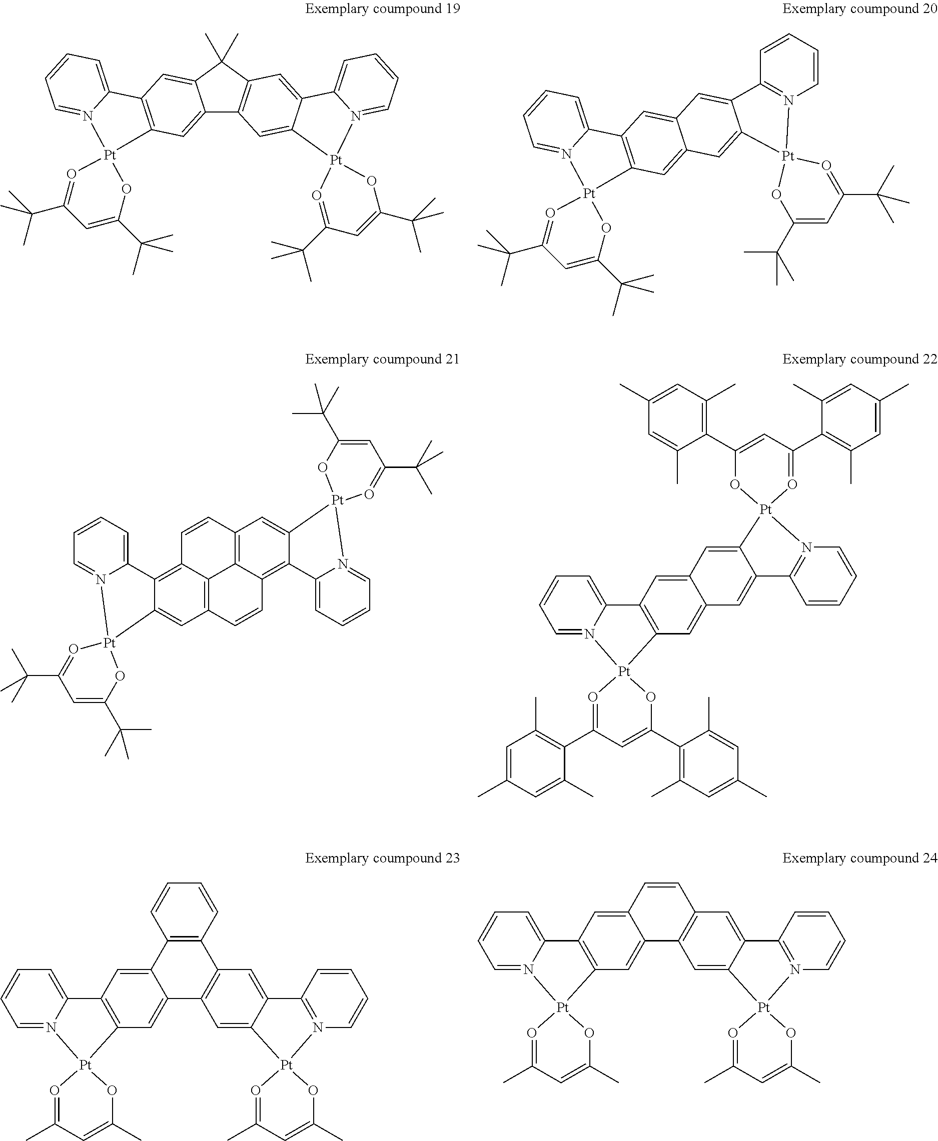

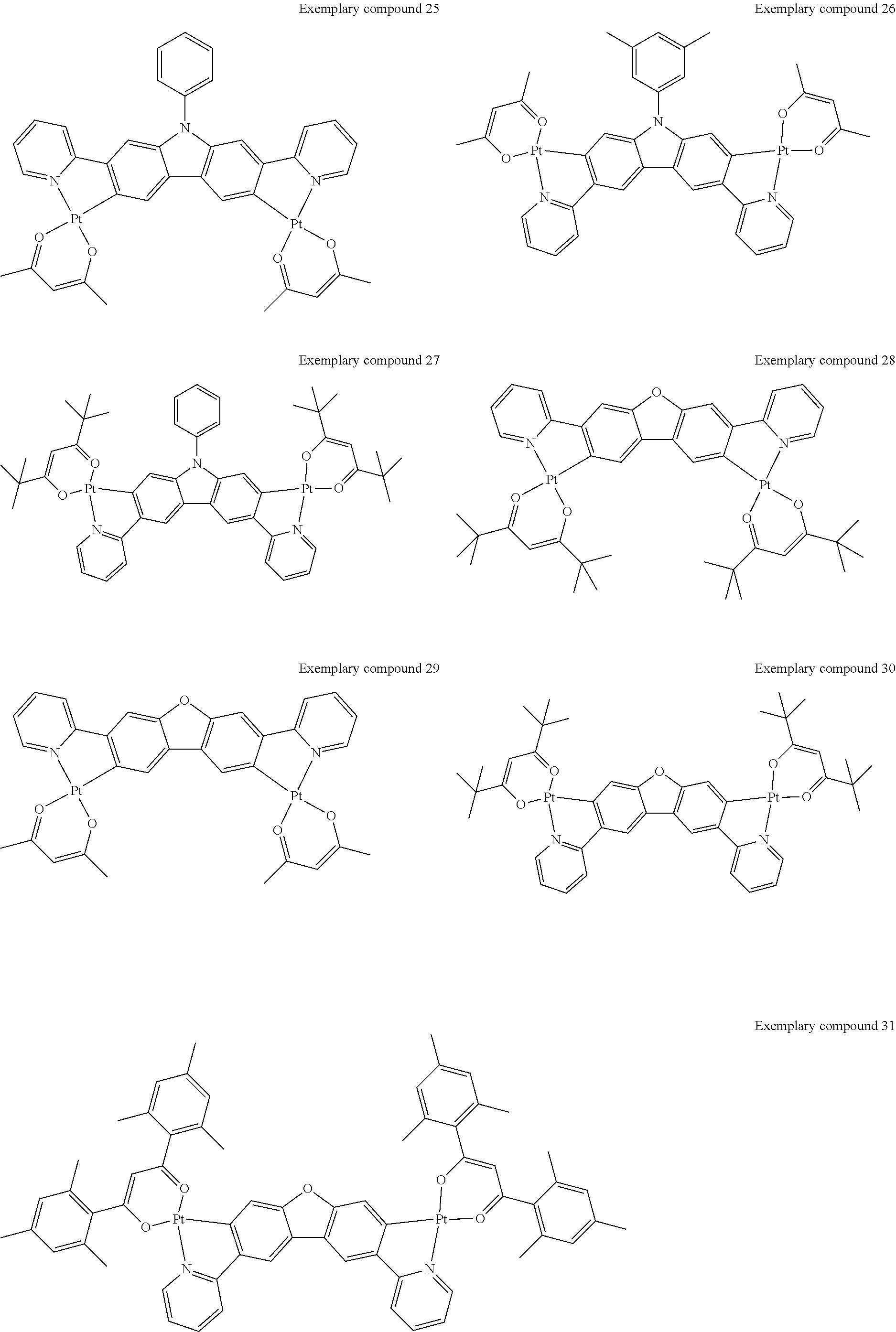

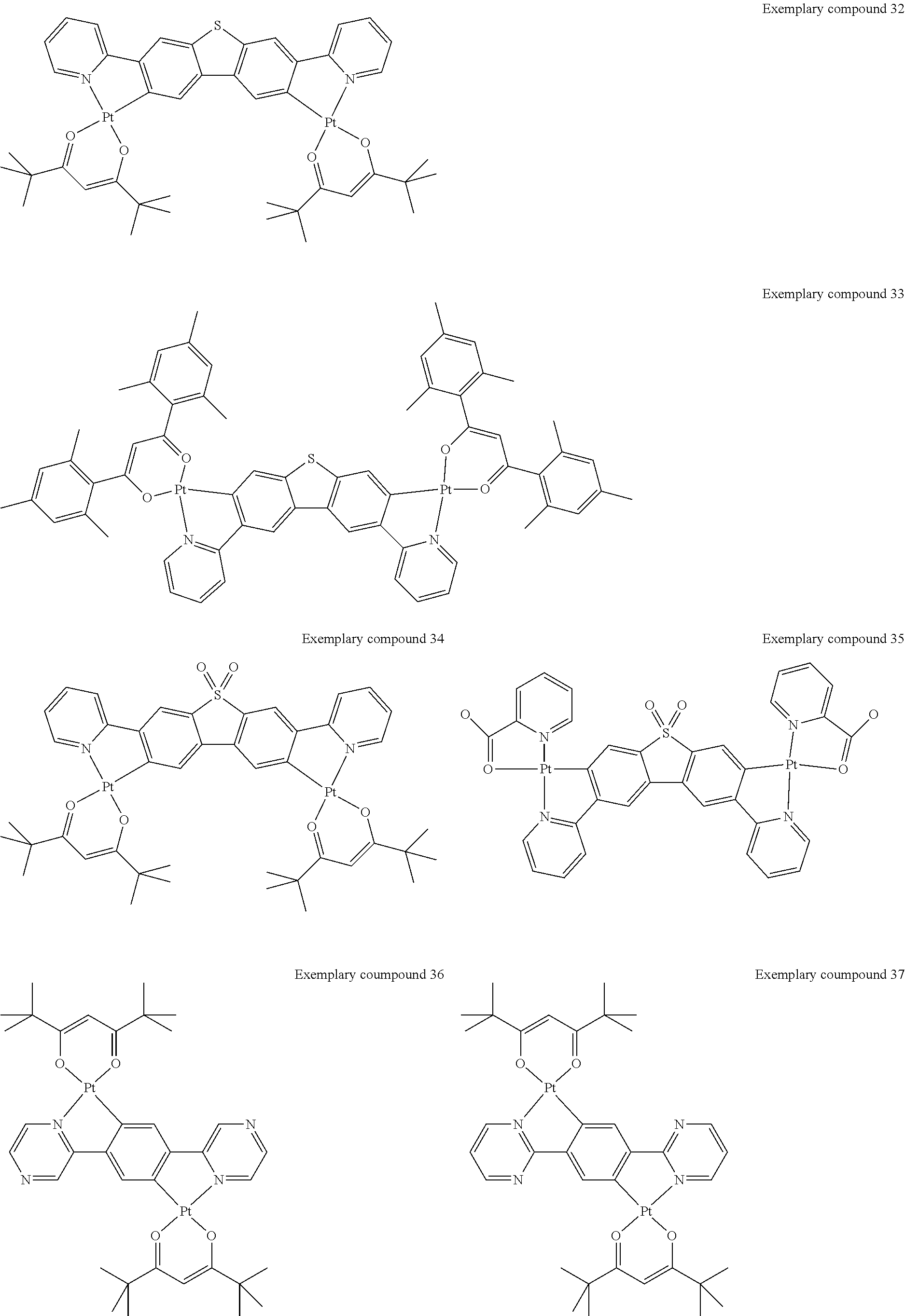

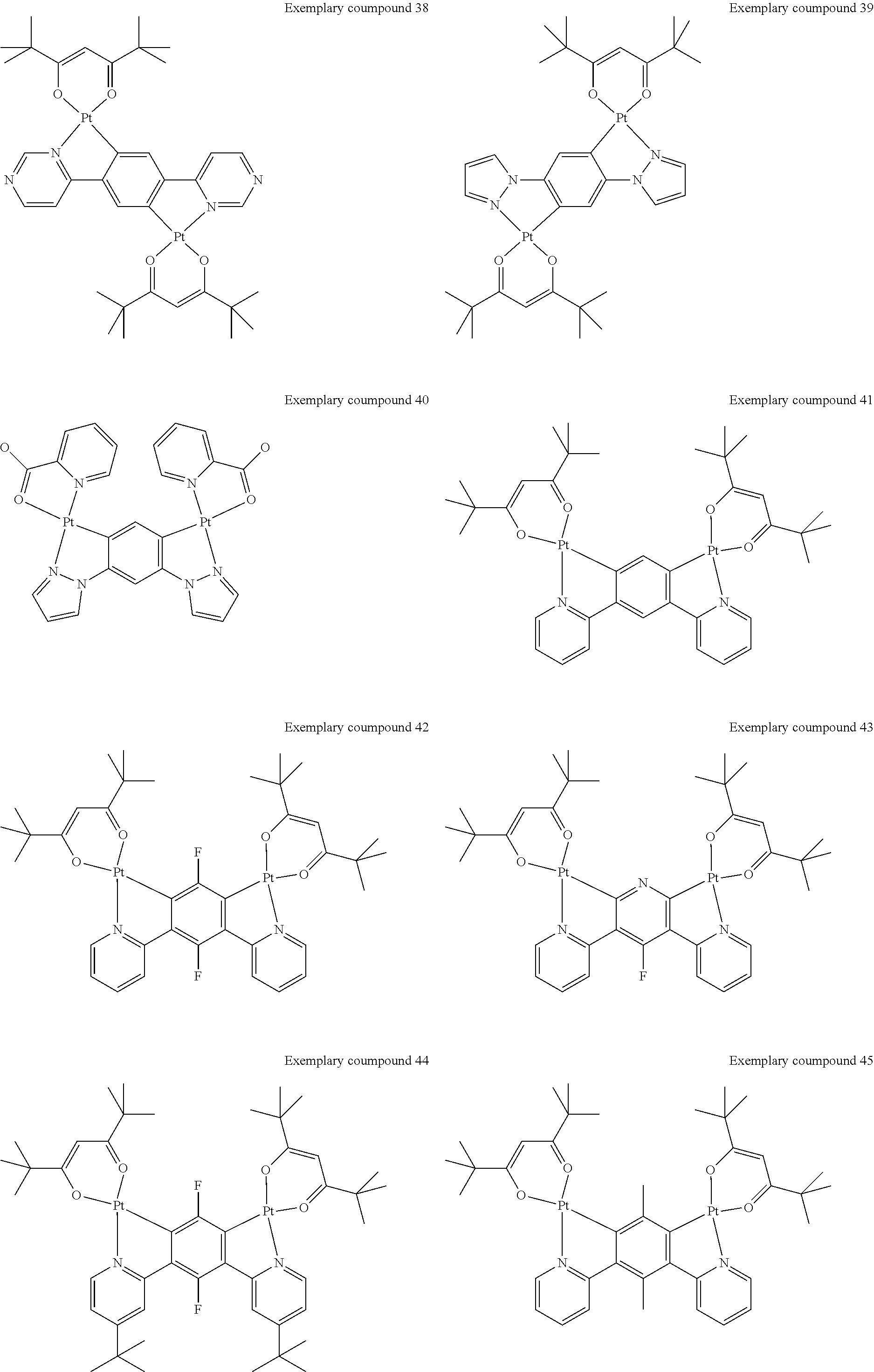

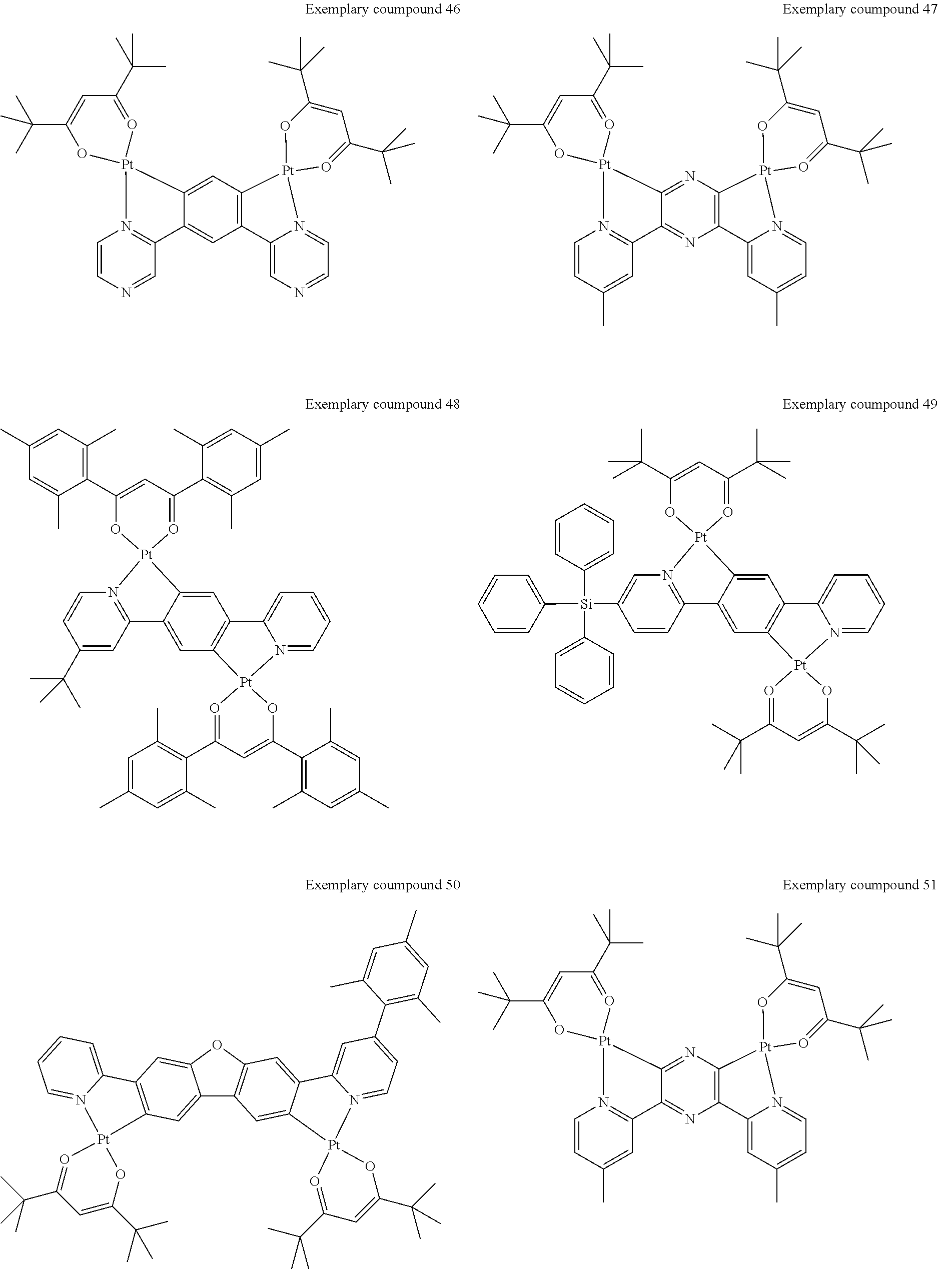

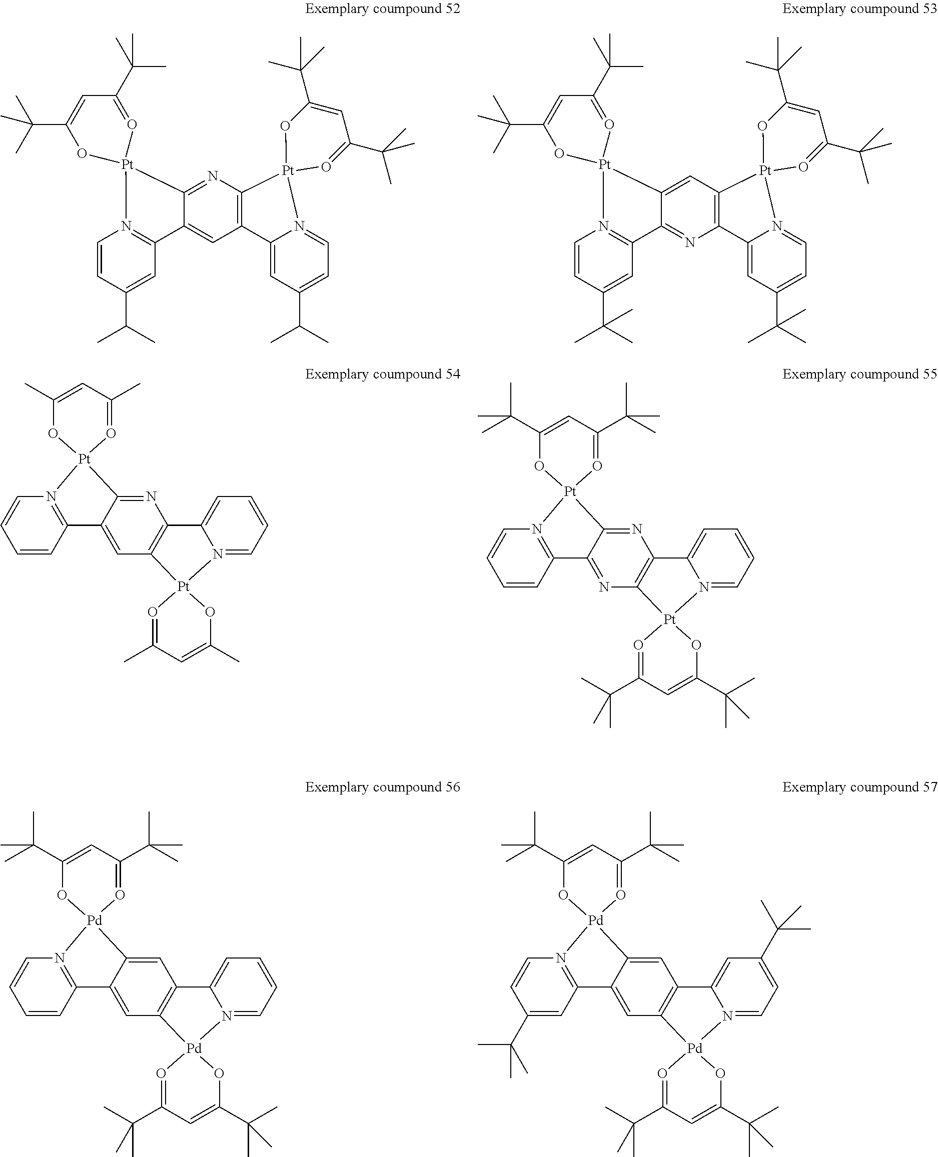

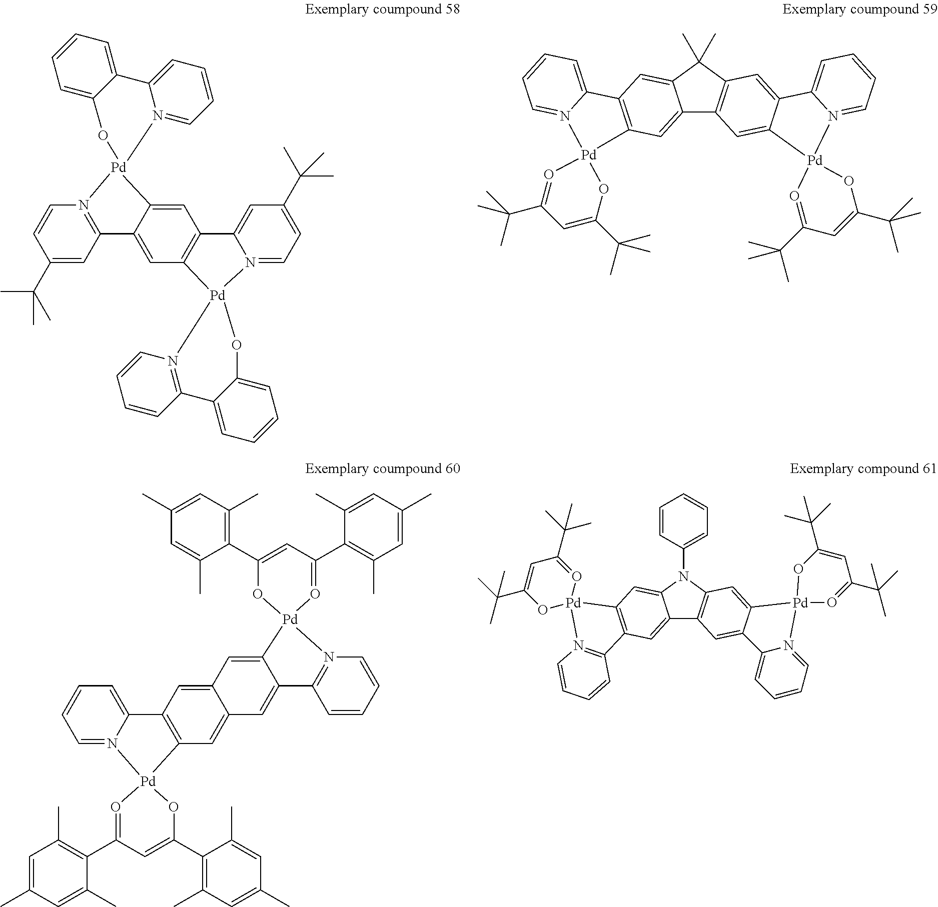

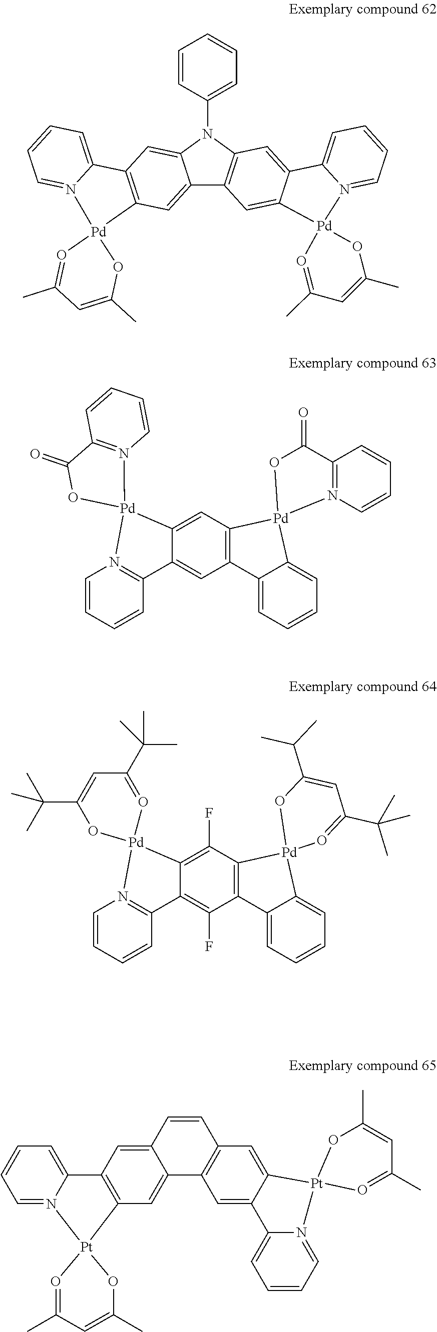

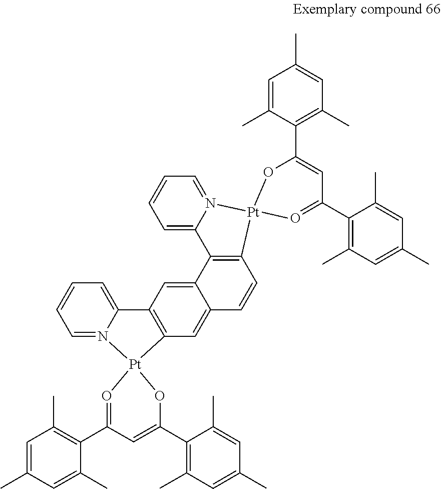

### Features

The metal complex according to the present embodiment is a binuclear complex having two Pt(JJ) or Pd(JJ) atoms as central metals. The features of this binuclear complex in terms of molecular structure are that (a) the metal complex has two metal centers and (b) the internal rotation of the conjugated system of the main ligand is suppressed by the two metal atoms.

The relationship between the molecular structure and emission characteristics will be described in more detail. With regard to (a), since the metal complex has two metal atoms serving as the luminescent centers, distortion of the molecular structure in the excited state is relieved, and consequently, the half-width (full width at half maximum (FWHM)) of the emission spectrum decreases. With regard to (b), the internal rotation of the conjugated system of the main ligand is suppressed, and non-radiative deactivation from the excited state is thereby suppressed to increase the photoluminescence quantum yield (PLQY).

In addition, (c) the metal complex preferably has high symmetry of the basic skeleton and more preferably has 2-fold rotational symmetry or mirror symmetry. Herein, the term “basic skeleton” refers to a skeleton in which the rings A and B have no substituents in general formula (1). When the basic skeleton has symmetry, the metal complex has a relatively uniform electron distribution of the excited state and the ground state involved in light emission, and distortion of the structure in the excited state decreases. It is considered that this further decreases the half-width of the emission spectrum. The substituents that the rings A and B may have may be introduced so as to break the symmetry of the basic skeleton but are preferably introduced so as to maintain the symmetry of the basic skeleton. That is, the organometallic complex according to the present embodiment preferably has high symmetry and more preferably has 2-fold rotational symmetry or mirror symmetry.

Thus, in the compounds according to the present embodiment, (a) and (b), and preferably (c) are involved in a complex manner, and a light-emitting material that is stable and has a small half-width and a high PLQY can be realized.

A description will be further given below with reference to Example compounds and Comparative example compounds. First, Example compounds for the present disclosure are shown. Example compound 01 is Exemplary compound 02, and Example compound 02 is Exemplary compound 19.

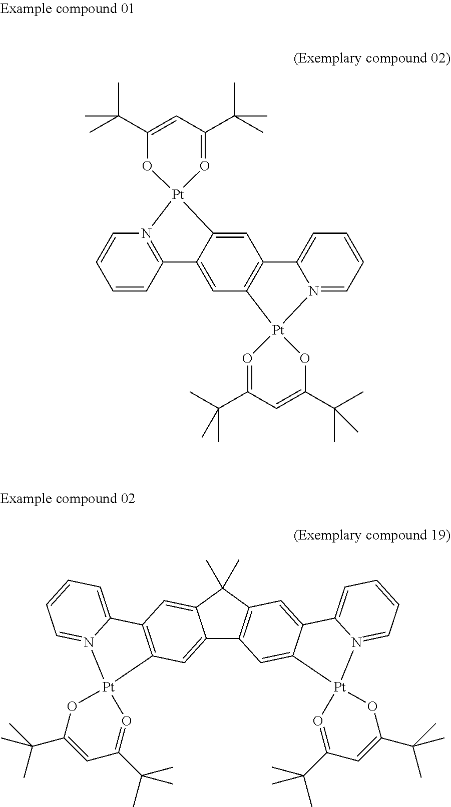

Next, Comparative example compounds for the present disclosure are shown. Comparative example compounds 01 and 02 are compounds produced in Examples described later. Comparative example compound 03 is a compound described in NPL 2. Comparative example compounds 04 and 05 are compounds described in NPL 3. Comparative example compound 06 is a compound described in NPL 4. Comparative example compound 07 is a compound described in PTL 1.

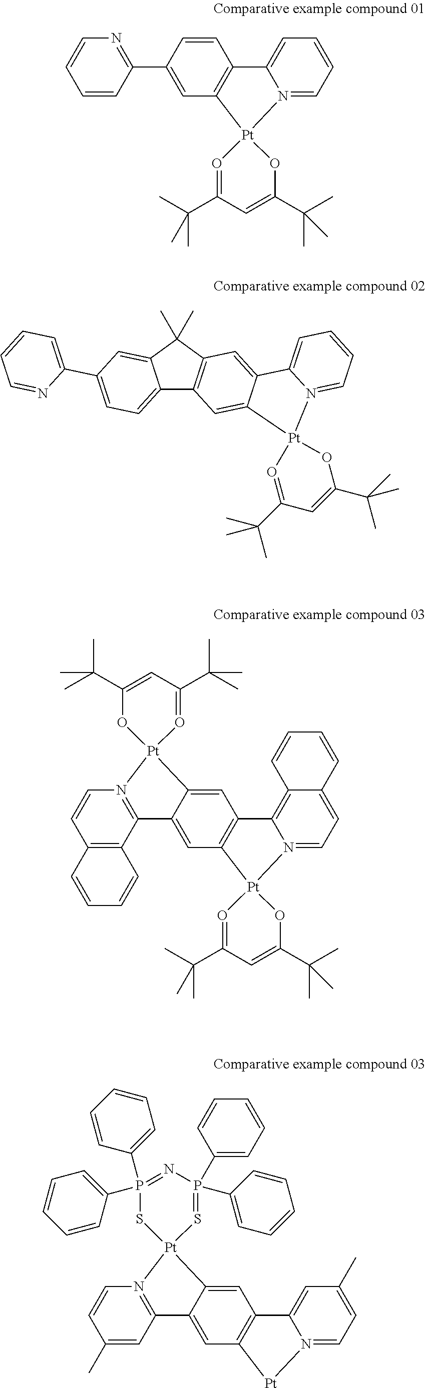

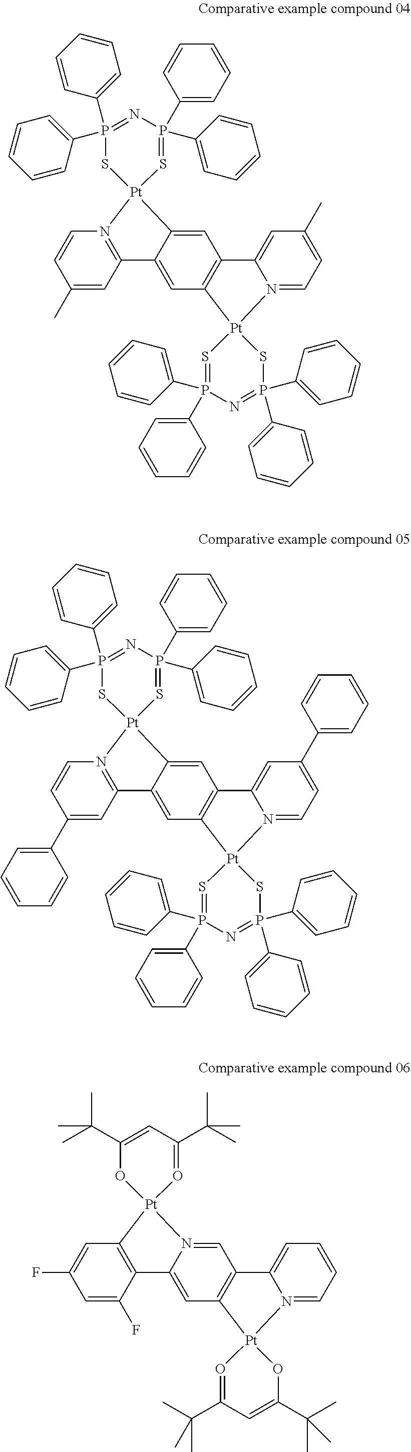

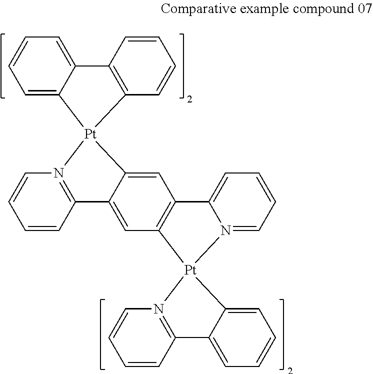

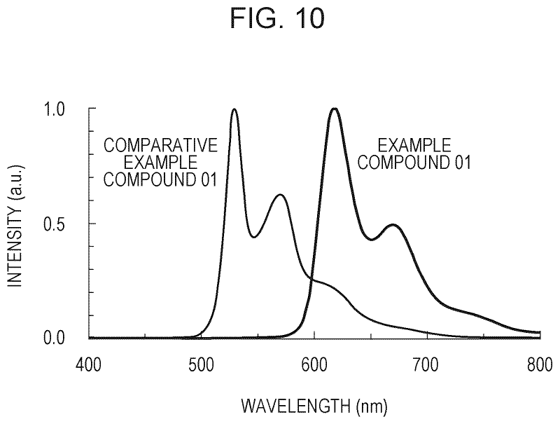

Comparative example compound 01 is a mononuclear Pt complex. FIG. 10 shows the comparison of emission spectra of Comparative example compound 01 and corresponding Example compound 01. The emission intensity of the second peak of Example compound 01 is lower than that of Comparative example compound 01. Since Example compound 01 has an emission intensity of the second peak of lower than 0.5 (i.e., 0.48), the half-width is determined only by the first peak, and the half-width is small. In contrast, since Comparative example compound 01 has an emission intensity of the second peak of 0.6 or more, the half-width extends over the first peak and the second peak, and the half-width is large. As shown in Table 1 of Examples described later, the half-widths of Example compound 01 and Comparative example compound 01 are 38 nm and 60 nm, respectively, showing that Example compound 01 has a small half-width.

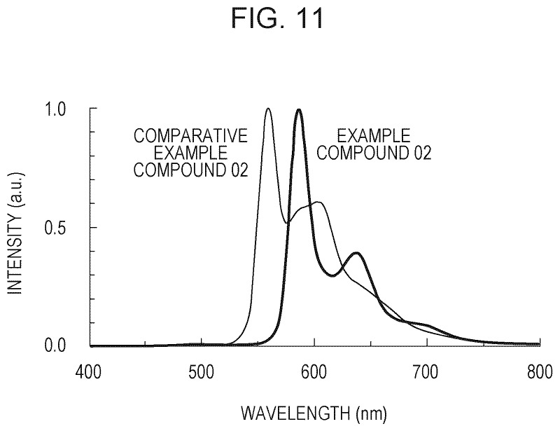

Similarly, FIG. 11 shows the comparison of emission spectra of Comparative example compound 02 and corresponding Example compound 02. As shown in Table 1 of Examples described later, the half-widths of Example compound 02 and Comparative example compound 02 are 22 nm and 65 nm, respectively, showing that the half-width of Example compound 02 is well controlled.

In addition, emission characteristic data of Comparative example compounds 03 to 07 is shown in Table 1 of Examples described later. Attention should be paid to the magnitudes of the half-widths. The half-widths of Example compounds are 22 nm to 38 nm, whereas the half-widths of Comparative example compounds are 60 nm to 100 nm or more, showing that the half-widths are effectively controlled in Example compounds. Comparative example compounds 04 and 05 are examples in which the auxiliary ligands that coordinate at S atoms have a strong influence on emission characteristics, and the auxiliary ligands degrade the emission characteristics. In Comparative example compound 06, the main ligand is not B-A-B, and the half-width cannot be controlled. Comparative example compound 07 is a binuclear iridium complex and has a half-width of 65 nm.

The inventors have conducted extensive studies to address the technical problems described above. Consequently, it has been found that the use of a binuclear Pd complex or binuclear Pt complex having a specific structure of the present disclosure can provide a metal complex light-emitting material in which distortion in the excited state is reduced and which has a small half-width, is stable, and achieves high efficiency.

### Organic Light-Emitting Device

An organic light-emitting device according to the present embodiment includes at least a first electrode and a second electrode, which are a pair of electrodes, and an organic compound layer disposed between the electrodes. In the organic light-emitting device of the present embodiment, the organic compound layer may be a single layer or a stack of a plurality of layers as long as the organic compound layer includes a light-emitting layer. The pair of electrodes may be an anode and a cathode.

When the organic compound layer is a stack of a plurality of layers, the organic compound layer may include a light-emitting layer. The organic compound layer may include, besides the light-emitting layer, for example, a hole injection layer, a hole transport layer, an electron-blocking layer, a hole/exciton-blocking layer, an electron transport layer, and an electron injection layer. The light-emitting layer may be a single layer or a stack of a plurality of layers. The hole transport layer and the electron transport layer are also referred to as charge transport layers.

In the organic light-emitting device of the present embodiment, the organometallic complex according to the present embodiment is contained in at least one layer in the organic compound layer. Specifically, the organometallic complex according to the present embodiment is contained in any of the hole injection layer, the hole transport layer, the electron-blocking layer, the light-emitting layer, the hole/exciton-blocking layer, the electron transport layer, the electron injection layer, and the like and is preferably contained in the light-emitting layer. The transport layers between the first electrode and the light-emitting layer can be collectively referred to as a first charge transport layer. The transport layers between the second electrode and the light-emitting layer can be collectively referred to as a second charge transport layer. That is, the light-emitting layer is in contact with the first charge transport layer and in contact with the second charge transport layer.

In the organic light-emitting device of the present embodiment, when the organometallic complex according to the present embodiment is contained in a light-emitting layer, the light-emitting layer may be a layer composed only of the organometallic complex according to the present embodiment or a layer that contains, in addition to the organometallic complex according to the present embodiment, a first organic compound and a second organic compound different from the first organic compound. The first organic compound may have a higher lowest excited triplet energy than the lowest excited triplet energy of the organometallic complex according to the present embodiment. The lowest excited triplet energy of the second organic compound may be equal to or higher than the lowest excited triplet energy of the organometallic complex of the present embodiment and equal to or lower than the lowest excited triplet energy of the first organic compound. When the light-emitting layer is a layer containing the first organic compound and the second organic compound, the first organic compound may be a host of the light-emitting layer. The second organic compound may be an assist material. The organometallic complex according to the present embodiment may be a guest or a dopant.

Herein, the host refers to, among the compounds that form the light-emitting layer, a compound having the highest mass proportion. The guest or dopant refers to, among the compounds that form the light-emitting layer, a compound that has a lower mass proportion than the host and that is responsible for main light emission. The assist material refers to, among the compounds that form the light-emitting layer, a compound that has a lower mass proportion than the host and that assists light emission of the guest. The assist material is also referred to as a second host.

When the organometallic complex according to the present embodiment is used as the guest of the light-emitting layer, the concentration of the guest is preferably 0.01% by mass or more and 20% by mass or less, more preferably 0.1% by mass or more and 10.0% by mass or less, based on the entire light-emitting layer. The entire light-emitting layer refers to the total mass of the compounds that form the light-emitting layer.

The lowest excited triplet energy of the first charge transport layer is preferably higher than the lowest excited triplet energy of the first organic compound. The lowest excited triplet energy of the second charge transport layer is preferably higher than the lowest excited triplet energy of the first organic compound. The lowest excited triplet energy of the charge transport layer can be estimated by the lowest excited triplet energy of the constituent material of the layer. When the charge transport layer is composed of a plurality of materials, the lowest excited triplet energy may be the lowest excited triplet energy of a compound having a high mass proportion.

The inventors have conducted various studies and have found that when the organometallic complex according to the present embodiment is used as a guest of a light-emitting layer, light output with high efficiency and high luminance is exhibited, and good roll-off characteristics are provided. This light-emitting layer may be composed of a single layer or multiple layers, and can also contain a light-emitting material having another emission color to thereby form a color mixture of the emission color of the present embodiment and the other emission color. The term “multiple layers” means a state in which a plurality of light-emitting layers such as the light-emitting layer and other light-emitting layers are stacked. In this case, the emission color of the organic light-emitting device is not limited to the same hue as the emission color of the single layer. More specifically, the emission color may be white or an intermediate color. In the case of white, red light, blue light, and green light may be emitted from the light-emitting layers to obtain white light, or complementary emission colors may be combined to obtain white light.

The organometallic complex according to the present embodiment can be used as a constituent material of an organic compound layer other than the light-emitting layer included in the organic light-emitting device of the present embodiment. Specifically, the organometallic complex may be used as a constituent material of the electron transport layer, the electron injection layer, the hole transport layer, the hole injection layer, the hole-blocking layer, or the like.

### Other Compounds

In producing the organic light-emitting device according to the present embodiment, publicly known low-molecular-weight and high-molecular-weight hole injection compounds or hole transport compounds, compounds serving as the host, light-emitting compounds, and electron injection compounds or electron transport compounds can be used in combination as necessary. Examples of these compounds will be described below.

The hole injection/transport material is preferably a material having a high hole mobility so as to facilitate hole injection from the anode and to enable the injected holes to be transported to the light-emitting layer. The hole injection/transport material is preferably a material having a high glass transition temperature in order to reduce degradation of the film quality, such as crystallization, in the organic light-emitting device. Examples of the low-molecular-weight and high-molecular-weight materials having a hole injection/transport property include triarylamine derivatives, arylcarbazole derivatives, phenylenediamine derivatives, triazole derivatives, oxadiazole derivatives, imidazole derivatives, stilbene derivatives, phthalocyanine derivatives, porphyrin derivatives, conductive polymers such as polyarylamine derivatives, polyvinylcarbazole derivatives, polythiophene derivatives, and PEDOT-PSS, copolymers thereof, and mixtures thereof. The above hole injection/transport materials are also suitable for use in an electron-blocking layer. Specific examples of the compound used as the hole injection/transport material are shown below, but of course, the hole injection/transport material is not limited thereto.

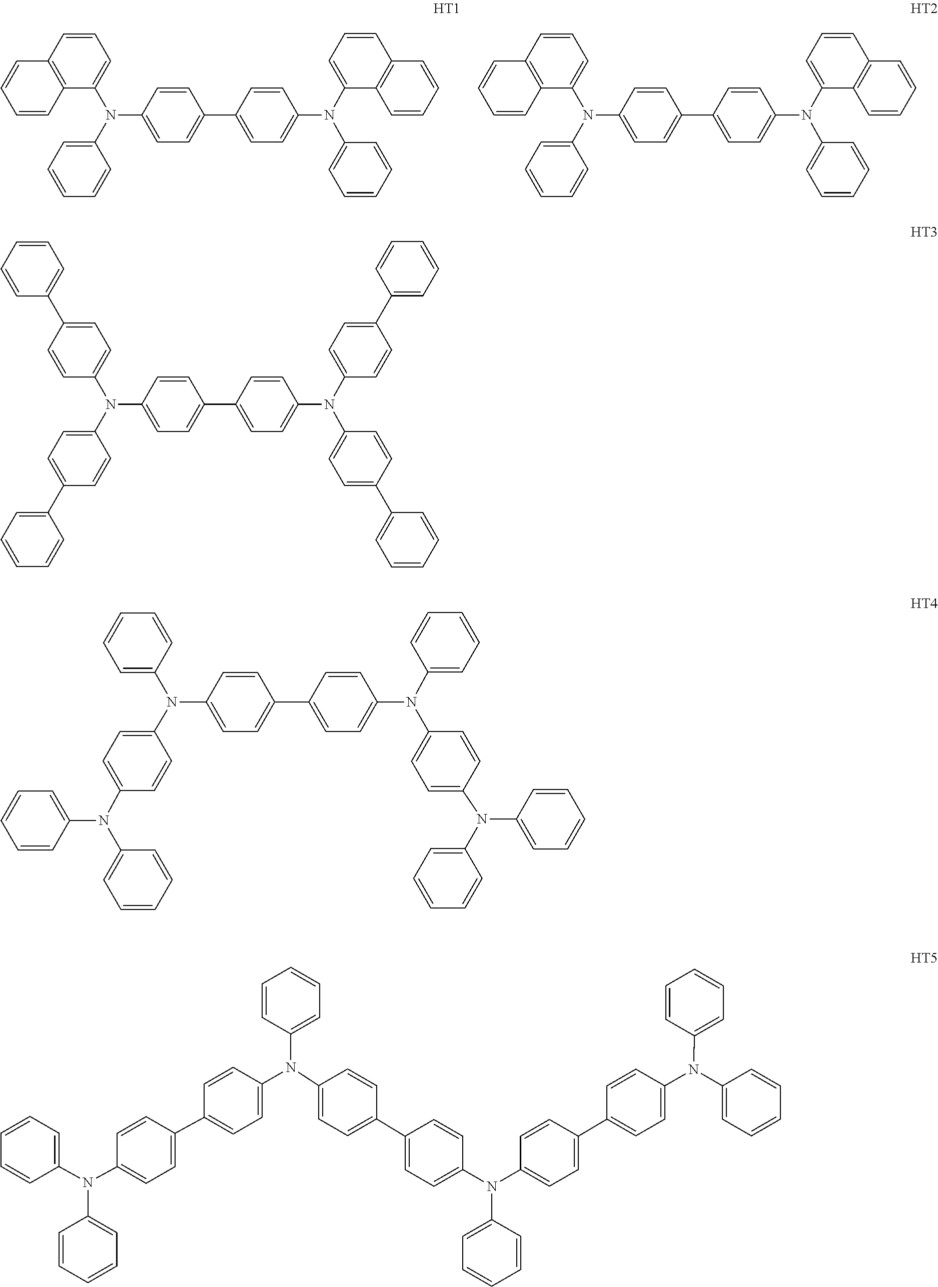

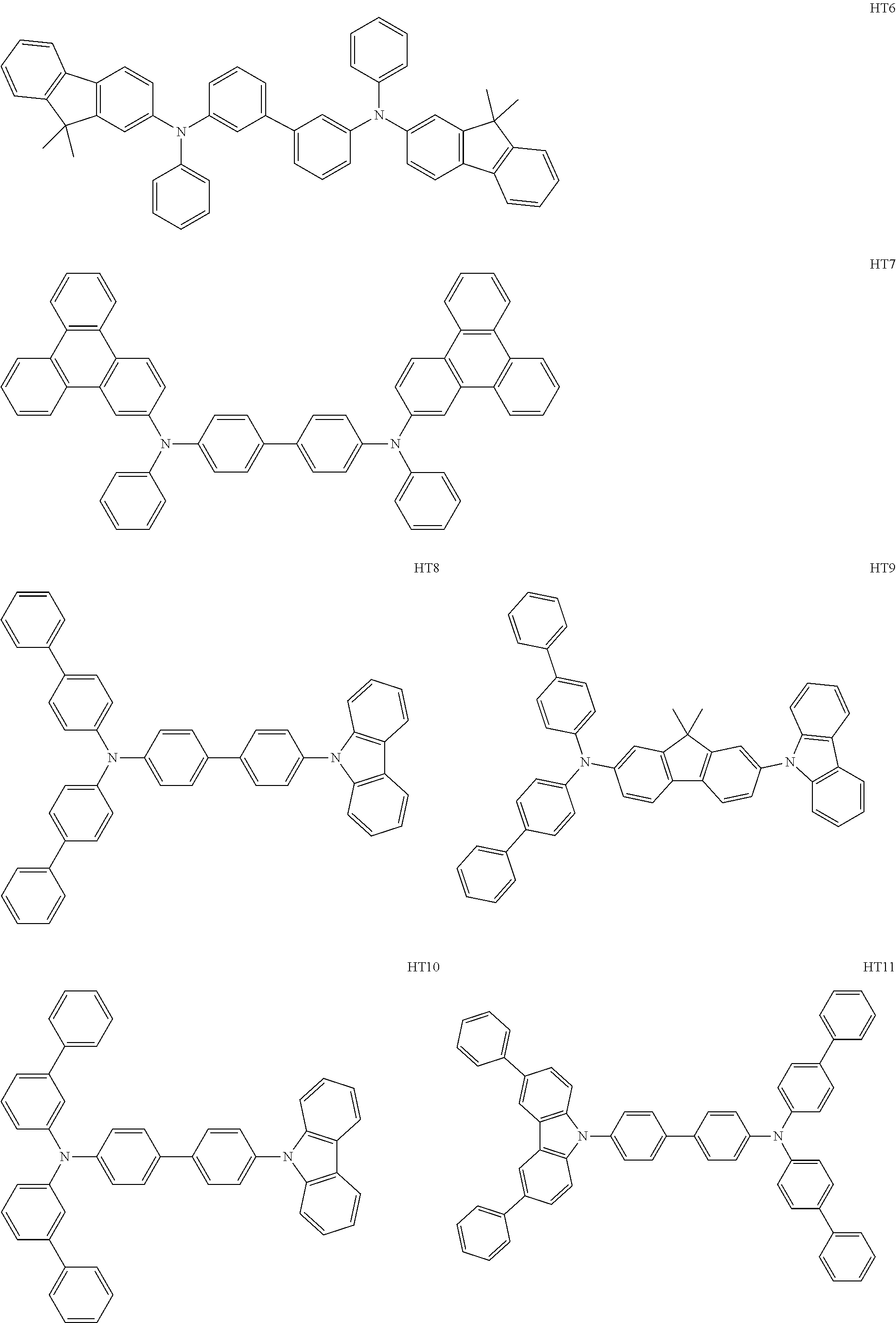

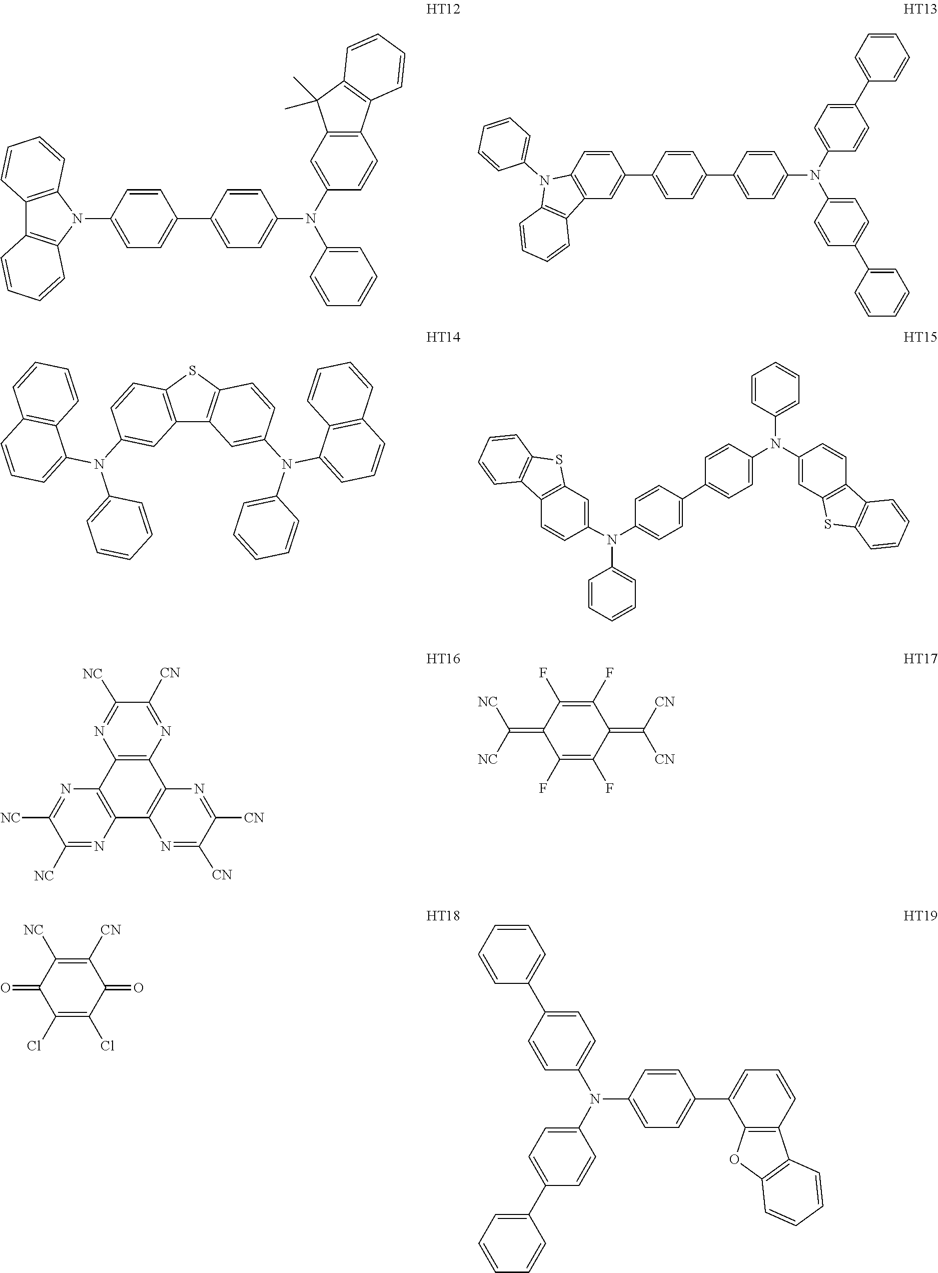

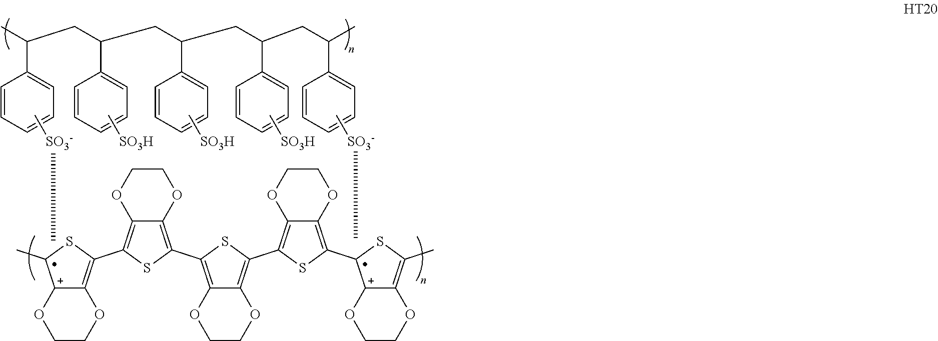

As the light-emitting material that is mainly associated with a light-emitting function, another light-emitting material can be added in addition to the organometallic complex according to an embodiment of the present disclosure. Examples of the other light-emitting material include fused ring compounds (such as fluorene derivatives, naphthalene derivatives, pyrene derivatives, perylene derivatives, tetracene derivatives, anthracene derivatives, and rubrene), quinacridone derivatives, coumarin derivatives, stilbene derivatives, organoaluminum complexes such as tris(8-quinolinolato)aluminum, iridium complexes such as tris(2-phenylpyridinato)iridium, platinum complexes, rhenium complexes, copper complexes, europium complexes, ruthenium complexes, and polymer derivatives such as poly(phenylene vinylene) derivatives, poly(fluorene) derivatives, and poly(phenylene) derivatives. Specific examples of the compound used as the light-emitting material are shown below, but of course, the light-emitting material is not limited thereto.

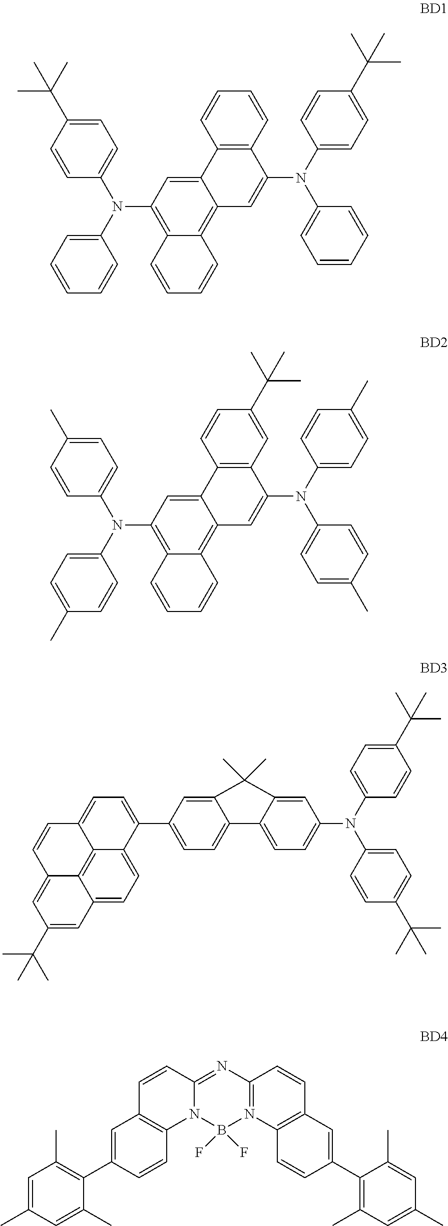

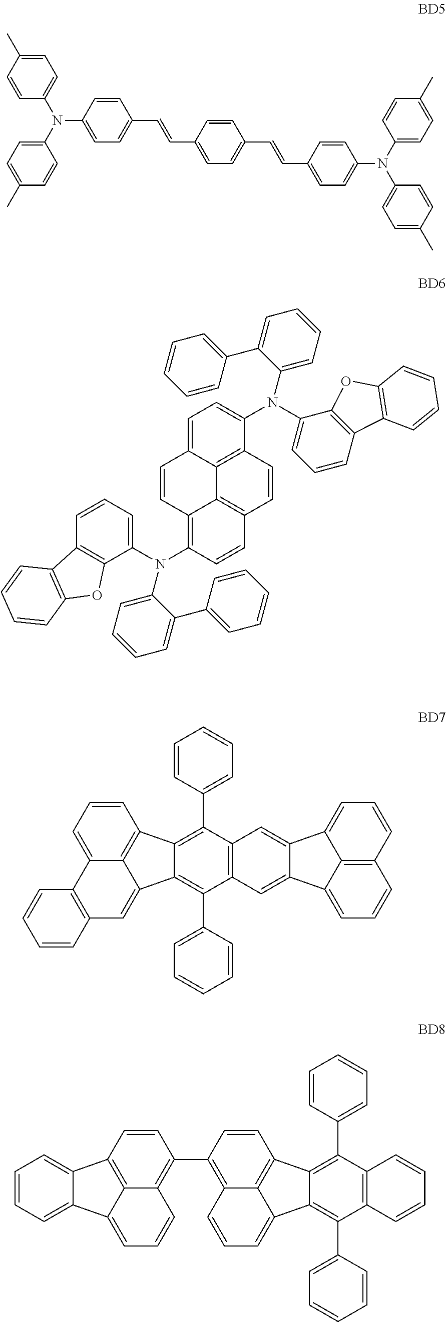

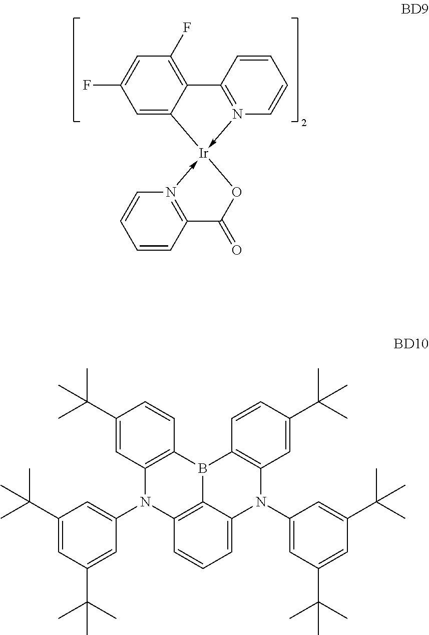

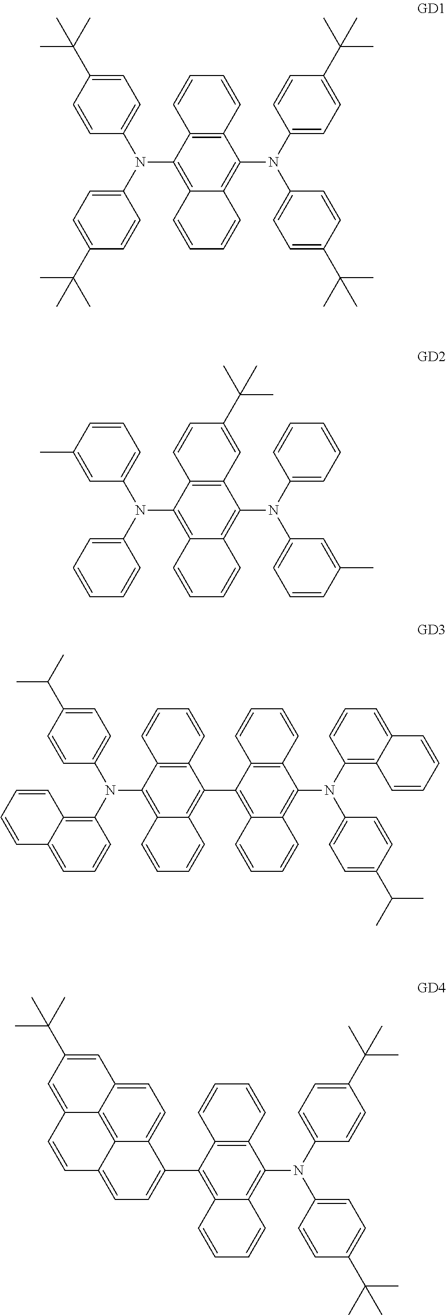

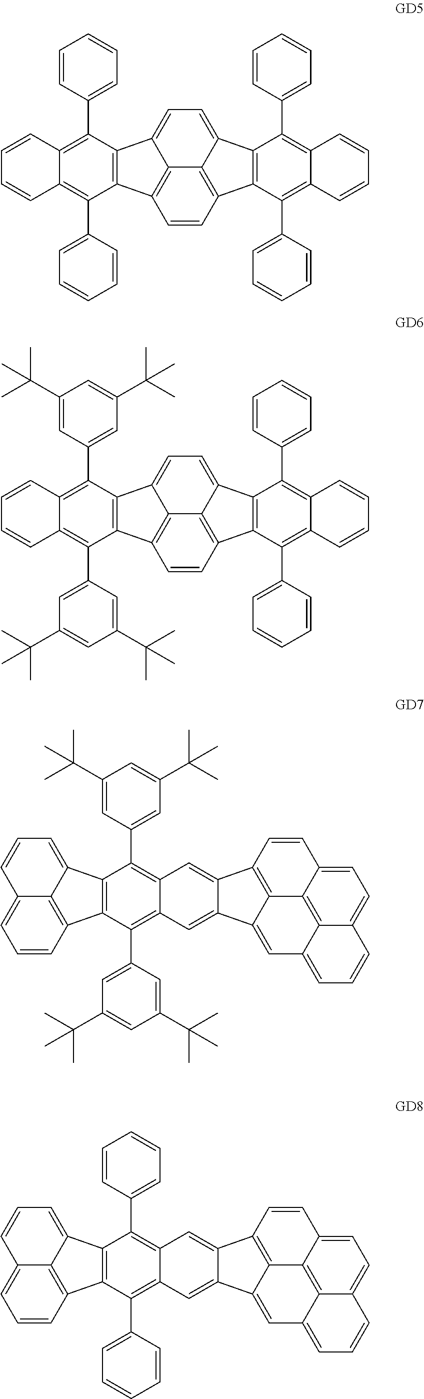

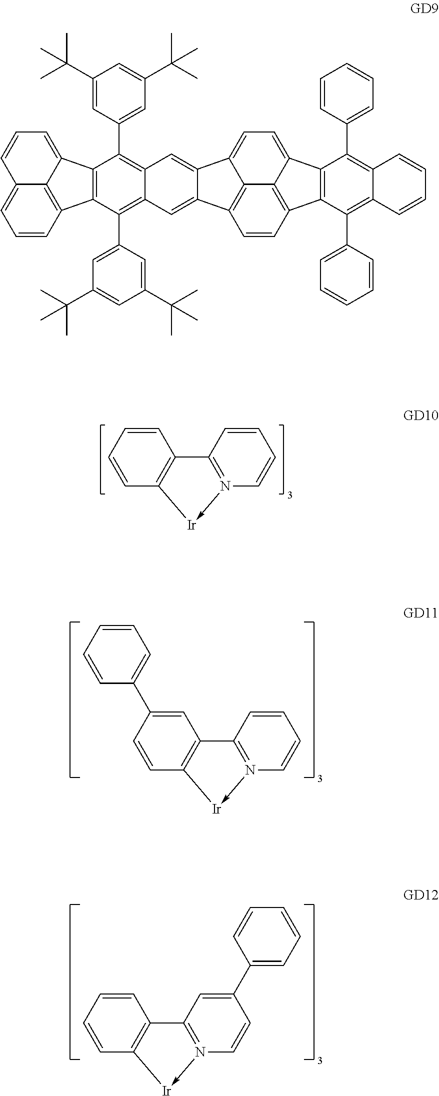

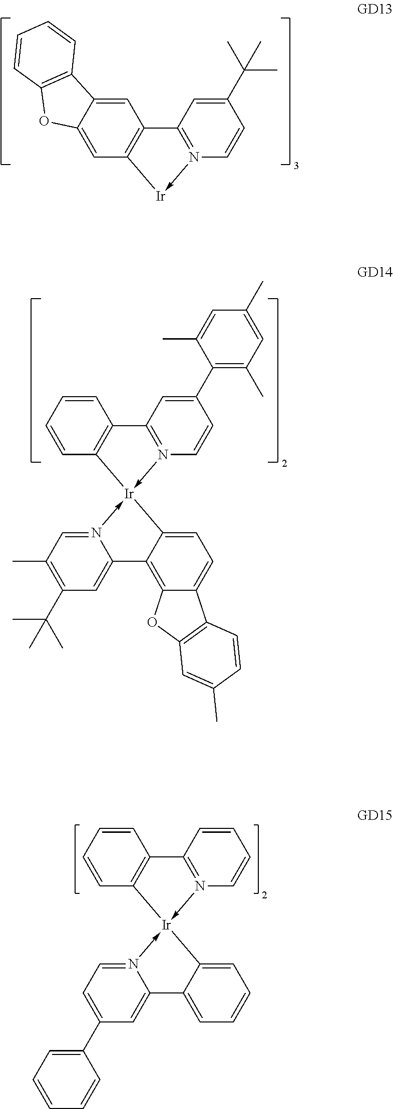

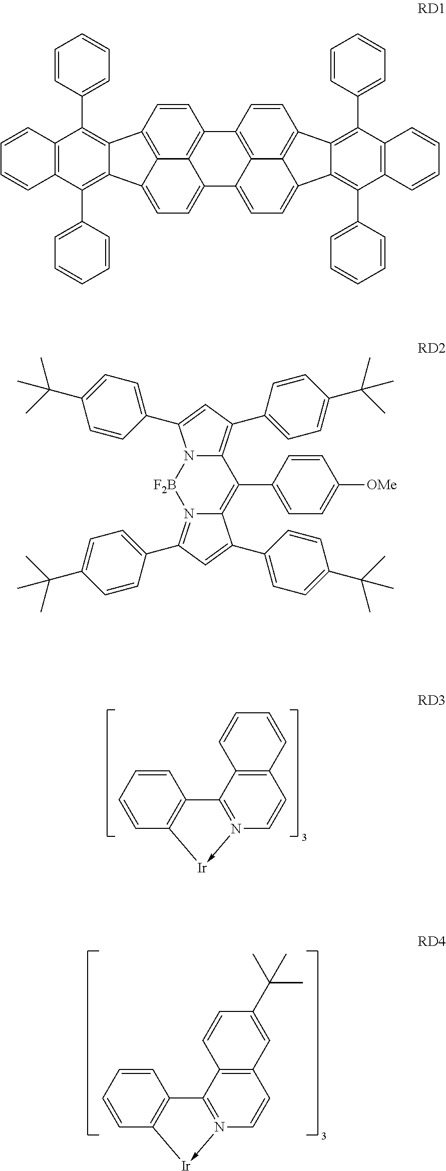

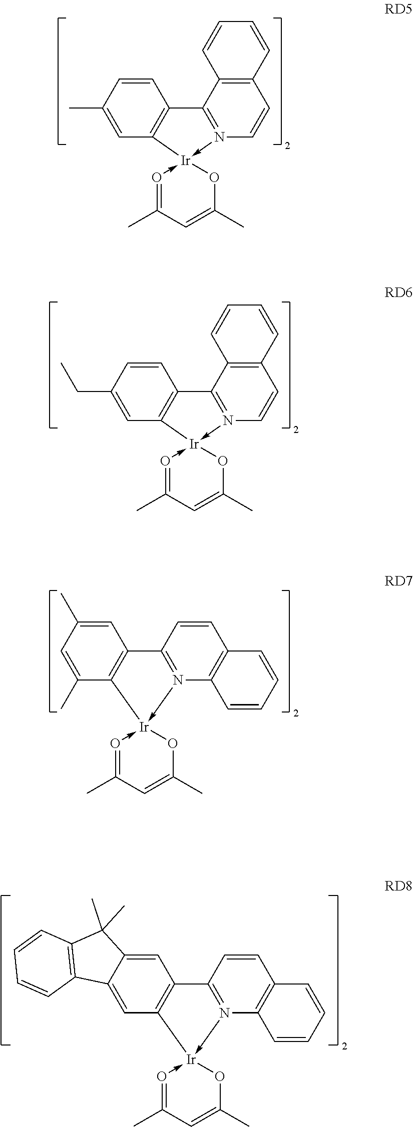

Examples of the light-emitting layer host or light-emitting assist material contained in the light-emitting layer include, in addition to aromatic hydrocarbon compounds and derivatives thereof, carbazole derivatives, dibenzofuran derivatives, dibenzothiophene derivatives, triazine derivatives, organoaluminum complexes such as tris(8-quinolinolato)aluminum, organoberyllium complexes, polymers such as polyphenylene derivatives, polyphenylene vinylene derivatives, polyfluorene derivatives, and polyvinyl carbazole derivatives, copolymers thereof, and mixtures thereof. Specific examples of the compound used as the light-emitting layer host or light-emitting assist material contained in the light-emitting layer are shown below, but of course, the light-emitting layer host or light-emission assist material is not limited thereto.

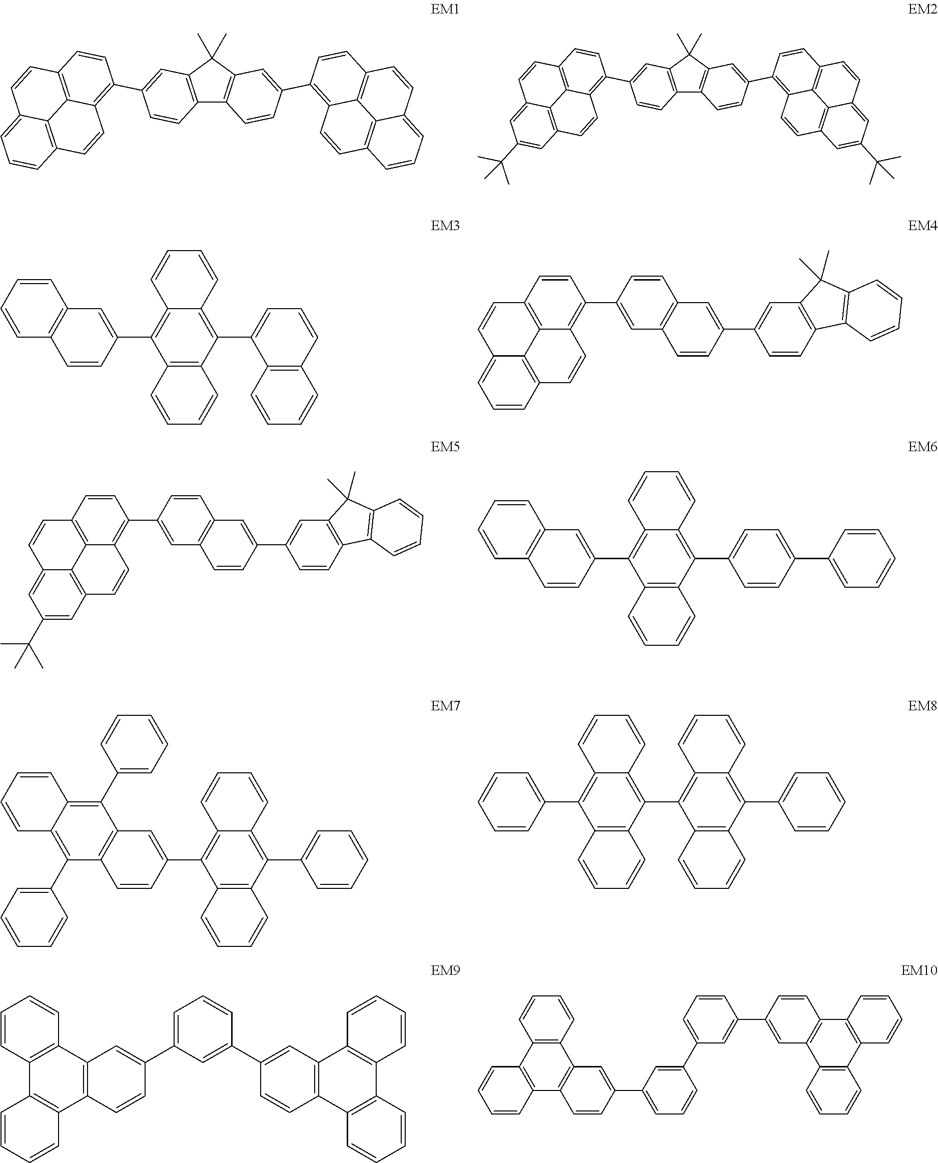

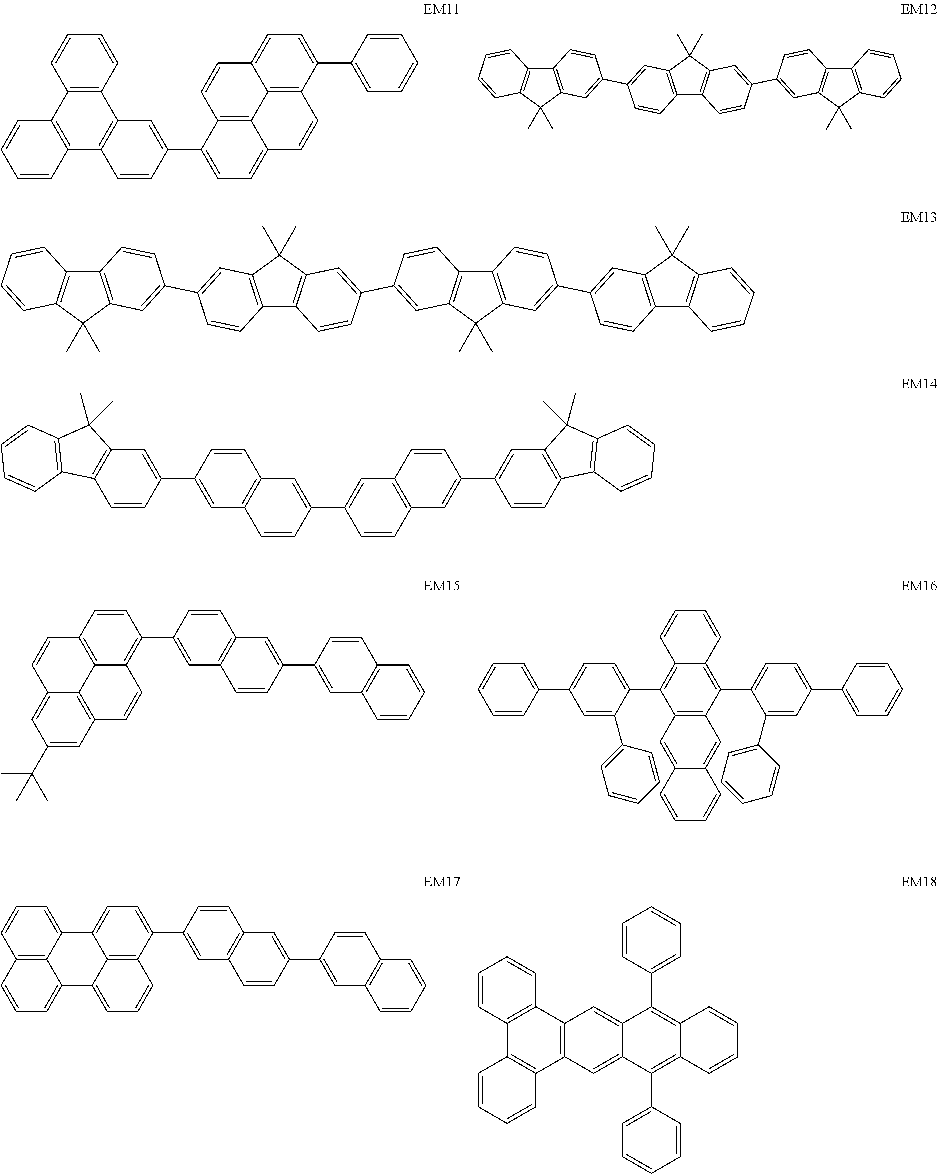

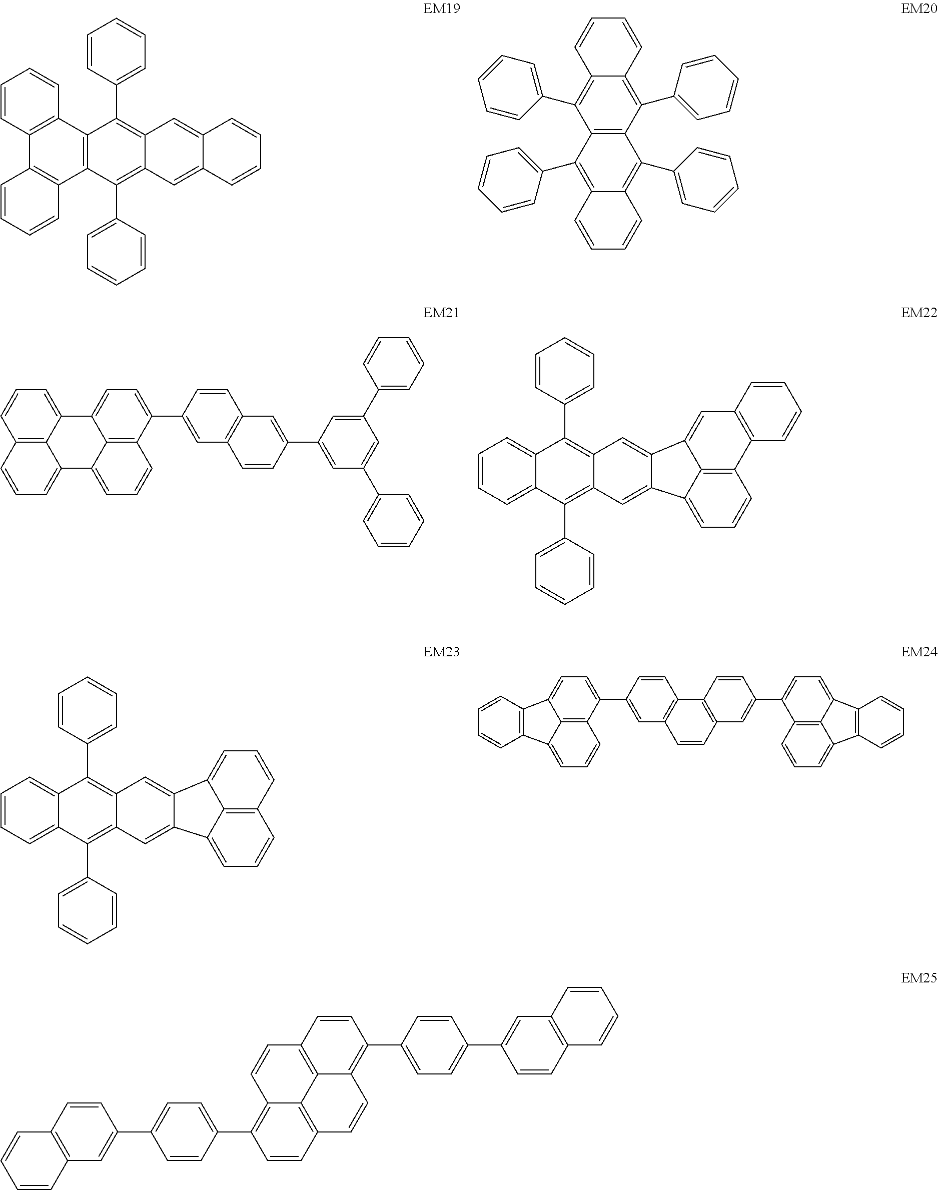

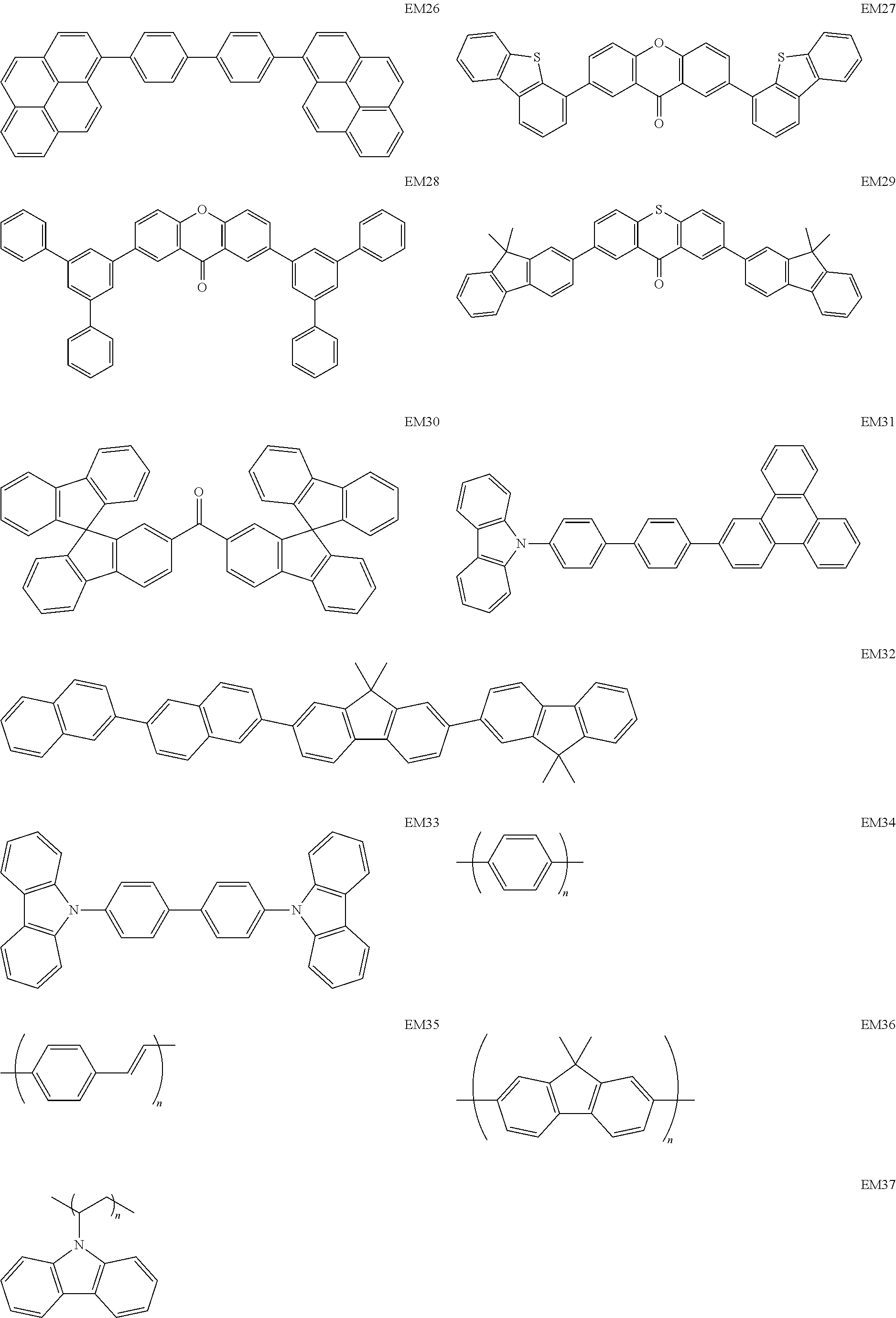

The electron transport material can be freely selected from materials capable of transporting electrons injected from the cathode to the light-emitting layer and is selected in consideration of, for example, the balance with the hole mobility of the hole transport material. Examples of the material having an electron transport property include oxadiazole derivatives, oxazole derivatives, pyrazine derivatives, triazole derivatives, triazine derivatives, quinoline derivatives, quinoxaline derivatives, phenanthroline derivatives, organoaluminum complexes, and fused ring compounds (such as fluorene derivatives, naphthalene derivatives, chrysene derivatives, and anthracene derivatives). The above electron transport materials are also suitable for use in a hole-blocking layer. Specific examples of the compound used as the electron transport material are shown below, but of course, the electron transport material is not limited thereto.

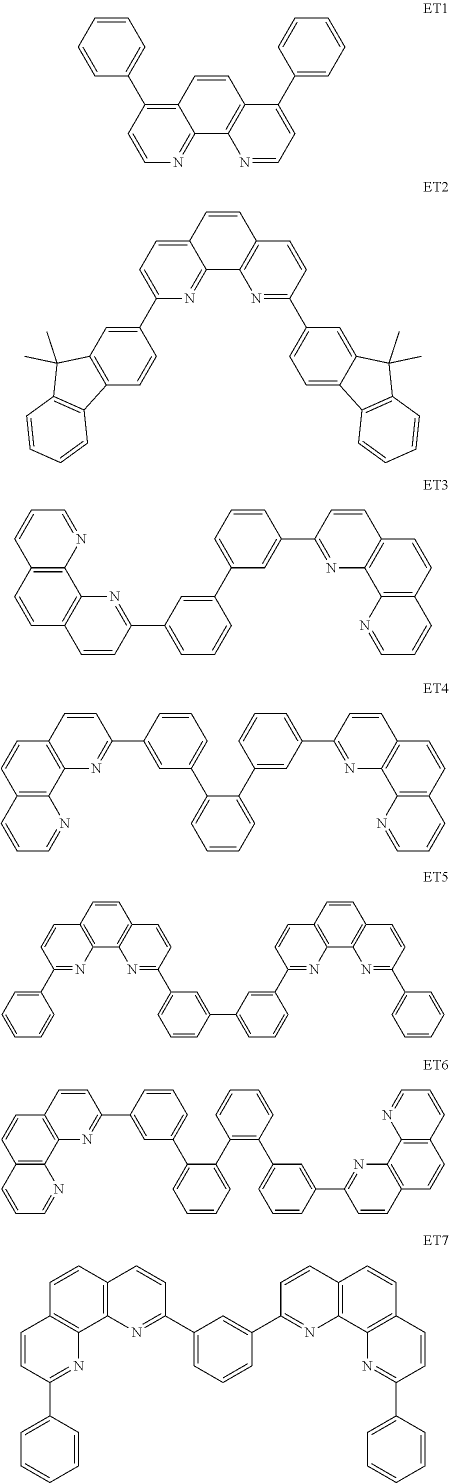

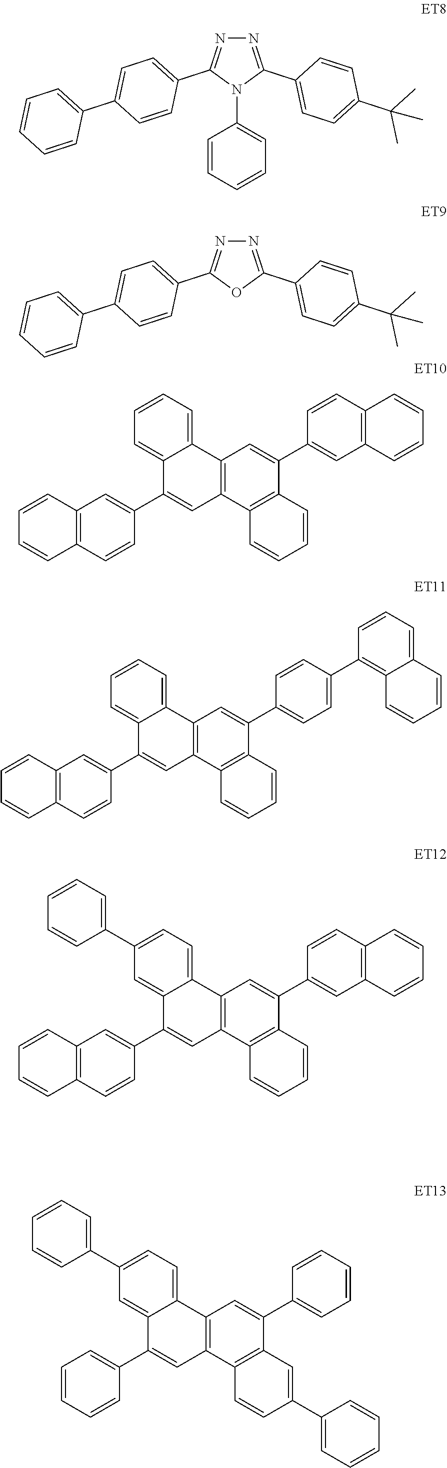

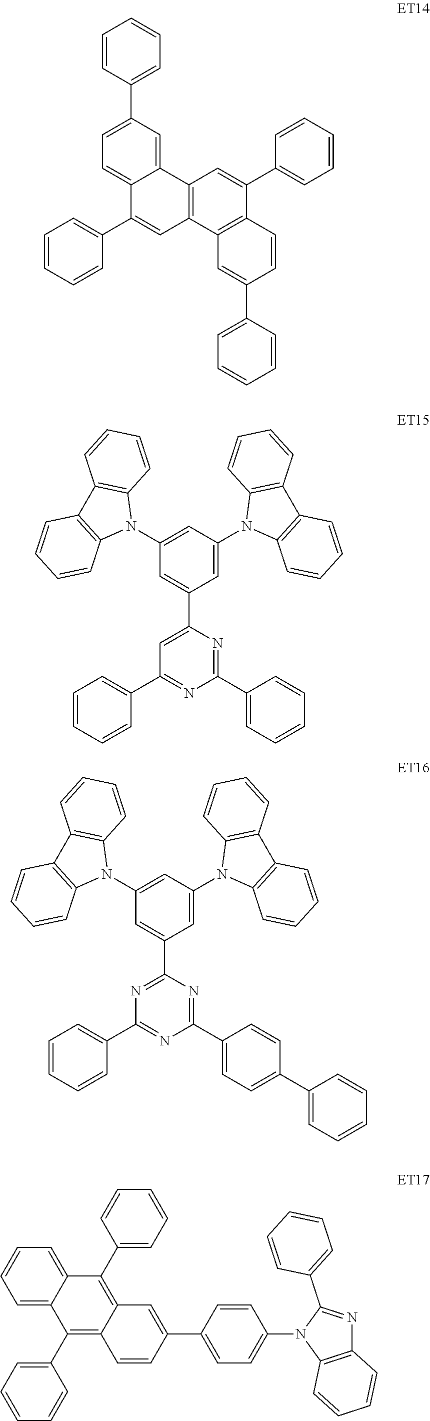

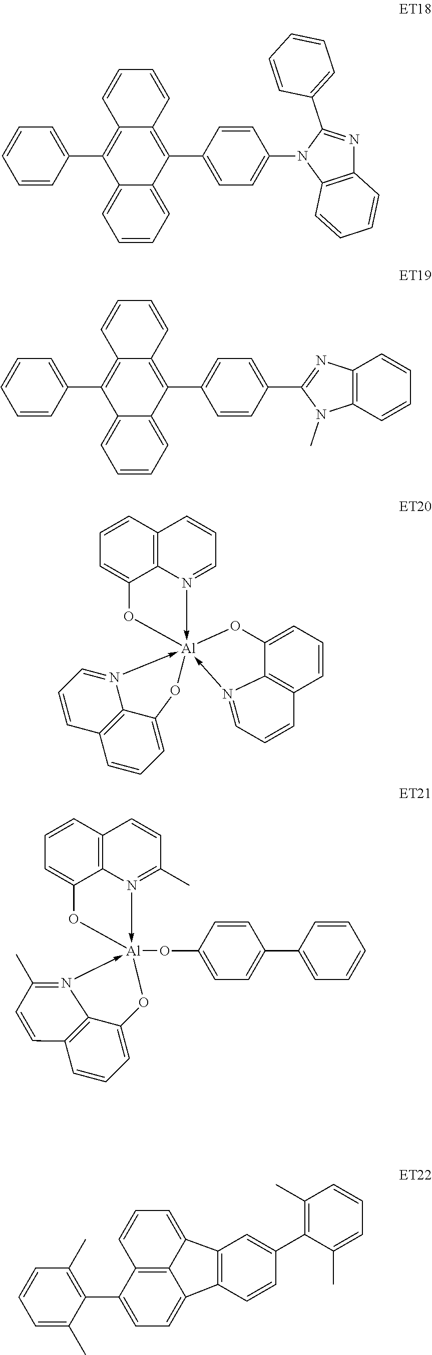

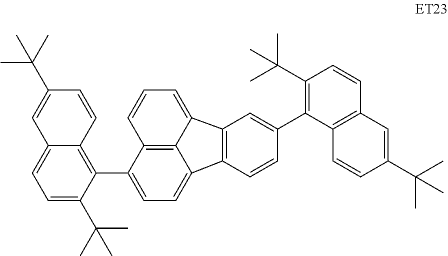 [SMILES: CC(C)(C)c1ccc2c(-c3ccc4c(c3)-c3cccc5c(-c6c(C(C)(C)C)ccc7cc(C(C)(C)C)ccc67)ccc-4c35)c(C(C)(C)C)ccc2c1]

The electron injection material can be freely selected from materials capable of easily injecting electrons from the cathode and is selected in consideration of, for example, the balance with the hole injection property. As the organic compound, n-type dopants and reducing dopants are also included. Examples thereof include alkali metal-containing compounds such as lithium fluoride, lithium complexes such as lithium quinolinol, benzimidazolidene derivatives, imidazolidene derivatives, fulvalene derivatives, and acridine derivatives.

### Structure of Organic Light-Emitting Device

The organic light-emitting device is produced by forming an insulating layer, a first electrode, an organic compound layer, and a second electrode on a substrate. A protective layer, a color filter, a microlens, etc., may be disposed on the second electrode. When a color filter is provided, a planarization layer may be disposed between the color filter and the protective layer. The planarization layer can be formed of an acrylic resin or the like. This also applies to the case where a planarization layer is disposed between the color filter and the microlens. One of the first electrode and the second electrode may be an anode, and the other may be a cathode.

### Substrate

Examples of the substrate include quartz substrates, glass substrates, silicon wafers, resin substrates, and metal substrates. Furthermore, switching elements, such as transistors, and wiring lines may be disposed on the substrate, and an insulating layer may be disposed thereon. The insulating layer may be formed of any material as long as a contact hole can be formed therein such that a wiring line can be connected to the first electrode and as long as insulation from an unconnected wiring line can be ensured. For example, a resin such as polyimide, silicon oxide, or silicon nitride can be used.

### Electrodes

A pair of electrodes can be used as the electrodes. The pair of electrodes may be an anode and a cathode. In the case where an electric field is applied in a direction in which the organic light-emitting device emits light, an electrode with a higher electric potential is the anode, and the other electrode is the cathode. In other words, the electrode that supplies holes to the light-emitting layer is the anode, and the electrode that supplies electrons is the cathode.

The material constituting the anode preferably has a work function that is as large as possible. Examples of the material that can be used include elemental metals such as gold, platinum, silver, copper, nickel, palladium, cobalt, selenium, vanadium, and tungsten; mixtures containing these metals; alloys of combinations thereof; and metal oxides such as tin oxide, zinc oxide, indium oxide, indium tin oxide (ITO), and indium zinc oxide. Examples thereof further include conductive polymers such as polyaniline, polypyrrole, and polythiophene.

These electrode substances may be used alone or in combination of two or more thereof. The anode may be formed of a single layer or a plurality of layers.

When the anode is used as a reflective electrode, for example, chromium, aluminum, silver, titanium, tungsten, molybdenum, an alloy thereof, or a stacked layer thereof can be used. The above materials can be used to function as a reflective film that does not have a role of an electrode. When the anode is used as a transparent electrode, a transparent conductive oxide layer such as an indium tin oxide (ITO) or indium zinc oxide layer may be used; however, the anode is not limited thereto. The electrodes can be formed by photolithography.

In contrast, the material constituting the cathode preferably has a small work function. Examples of the material include alkali metals such as lithium; alkaline earth metals such as calcium; elemental metals such as aluminum, titanium, manganese, silver, lead, and chromium; and mixtures containing these metals. Alloys of combinations of these elemental metals can also be used. For example, magnesium-silver, aluminum-lithium, aluminum-magnesium, silver-copper, and zinc-silver can be used. Metal oxides such as indium tin oxide (ITO) can also be used. These electrode substances may be used alone or in combination of two or more thereof. The cathode may have a single-layer structure or a multilayer structure. In particular, silver is preferably used. To reduce the aggregation of silver, a silver alloy is more preferably used. The alloying ratio is not limited as long as the aggregation of silver can be reduced. The ratio of silver to another metal may be, for example, 1:1 or 3:1.

The cathode is not particularly limited. The cathode may be a conductive oxide layer made of ITO or the like to provide a top-emission device. Alternatively, the cathode may be a reflective electrode made of aluminum (Al) or the like to provide a bottom-emission device. The method for forming the cathode is not particularly limited; however, for example, a DC or AC sputtering method is more preferably used because good film coverage is achieved and thus the resistance is easily reduced.

### Organic Compound Layer

The organic compound layer may be composed of a single layer or a plurality of layers. When the organic compound layer includes a plurality of layers, the layers may be referred to as a hole injection layer, a hole transport layer, an electron-blocking layer, a light-emitting layer, a hole-blocking layer, an electron transport layer, or an electron injection layer depending on their functions. The organic compound layer is mainly composed of an organic compound and may contain inorganic atoms and an inorganic compound. For example, the organic compound layer may contain copper, lithium, magnesium, aluminum, iridium, platinum, molybdenum, zinc, or the like. The organic compound layer may be disposed between the first electrode and the second electrode and may be disposed in contact with the first electrode and the second electrode.

The organic compound layers (such as a hole injection layer, a hole transport layer, an electron-blocking layer, a light-emitting layer, a hole-blocking layer, an electron transport layer, and an electron injection layer) constituting the organic light-emitting device according to one embodiment of the present disclosure are formed by the methods described below.

The organic compound layers constituting the organic light-emitting device according to one embodiment of the present disclosure can be formed by a dry process, such as a vacuum evaporation method, an ionized deposition method, sputtering, or plasma. Instead of the dry process, it is also possible to employ a wet process involving dissolving a material in an appropriate solvent, and then forming a layer by a publicly known coating method (for example, a spin coating method, a casting method, a microgravure coating method, a gravure coating method, a bar coating method, a roll coating method, a wire bar coating method, a dip coating method, a spray coating method, a screen printing method, a flexographic printing method, an offset printing method, an ink jet printing method, a capillary coating method, or a nozzle coating method). Of these, a vacuum evaporation method, an ionized deposition method, an ink jet printing method, a nozzle coating method, and the like are suitable for producing an organic light-emitting device having a large area.

When the layers are formed by a vacuum evaporation method, a coating method using a solution, or the like, the layers are unlikely to undergo, for example, crystallization and have good stability over time. When films are formed by a coating method, the materials can be combined with appropriate binder resins to form the films.

Examples of the binder resins include, but are not limited to, polyvinylcarbazole resins, polycarbonate resins, polyester resins, acrylonitrile-butadiene-styrene (ABS) resins, acrylic resins, polyimide resins, phenolic resins, epoxy resins, silicone resins, and urea resins.

These binder resins may be used alone as a homopolymer or a copolymer or in combination as a mixture of two or more thereof. Furthermore, publicly known additives such as a plasticizer, an oxidation inhibitor, and an ultraviolet absorbent may be optionally used in combination.

The thickness of each of the layers in the organic light-emitting device is usually preferably 1 nm or more and 10 μm or less. In particular, the thickness of the light-emitting layer of the organic compound layer is preferably 10 nm or more and 100 nm or less in order to obtain effective emission characteristics.

### Protective Layer

A protective layer may be disposed on the second electrode. For example, a glass member including a moisture absorbent is bonded to the second electrode to reduce the permeation of water or the like into the organic compound layer. Thus, the occurrence of display defects can be reduced. In another embodiment, a passivation film composed of silicon nitride or the like may be disposed on the second electrode to reduce the permeation of water or the like into the organic compound layer. For example, after the formation of the second electrode, the resulting substrate may be transferred to another chamber without breaking the vacuum, and a protective layer may be formed thereon by forming a silicon nitride film having a thickness of 2 μm by a CVD method. After the film deposition by the CVD method, a protective layer may be formed by an atomic layer deposition method (ALD method). The material of the film formed by the ALD method is not limited and may be, for example, silicon nitride, silicon oxide, or aluminum oxide. Silicon nitride may be further deposited by the CVD method on the film formed by the ALD method. The film formed by the ALD method may have a smaller thickness than the film formed by the CVD method. Specifically, the film thickness may be 50% or less, even 10% or less.

### Color Filter

A color filter may be disposed on the protective layer. For example, a color filter may be disposed on another substrate in consideration of the size of the organic light-emitting device, and this substrate may be bonded to the substrate having the organic light-emitting device thereon. Alternatively, a color filter may be formed on the aforementioned protective layer by photolithographic patterning. The color filter may be formed of a polymer.

### Planarization Layer

A planarization layer may be disposed between the color filter and the protective layer. The planarization layer is formed in order to reduce unevenness of the underlying layer. In some cases, the planarization layer is referred to as a material resin layer without limiting the purpose thereof. The planarization layer may be formed of an organic compound. The organic compound may be a low-molecular-weight organic compound or a high-molecular-weight organic compound, but is preferably a high-molecular-weight organic compound.

The planarization layer may be disposed on and under the color filter, and both the planarization layers may be formed of the same material or different materials. Specific examples of the material include polyvinylcarbazole resins, polycarbonate resins, polyester resins, ABS resins, acrylic resins, polyimide resins, phenolic resins, epoxy resins, silicone resins, and urea resins.

### Microlens

An organic light-emitting device may include an optical member such as a microlens on the light-emitting side. The microlens can be composed of an acrylic resin, an epoxy resin, or the like. The microlens may be used for the purposes of increasing the amount of light extracted from the organic light-emitting device and controlling the direction of the extracted light. The microlens may have a hemispherical shape. When the microlens has a hemispherical shape, among tangents in contact with the hemisphere, there is a tangent parallel to the insulating layer, and the contact point between the tangent and the hemisphere is the apex of the microlens. The apex of the microlens can be determined in the same manner in any sectional view. That is, among the tangents in contact with the semicircle of the microlens in the sectional view, there is a tangent parallel to the insulating layer, and the contact point between the tangent and the semicircle is the apex of the microlens.

The midpoint of the microlens can also be defined. In a section of the microlens, a line segment extending from a point at which an arc shape ends to another point at which the arc shape ends is assumed, and the midpoint of the line segment can be referred to as the midpoint of the microlens. The section used to determine the apex and the midpoint may be a section perpendicular to the insulating layer.

### Opposite Substrate

An opposite substrate may be disposed on the planarization layer. The opposite substrate is disposed at a position that opposes the aforementioned substrate and thus is referred to as an opposite substrate. The material constituting the opposite substrate may be the same as that of the aforementioned substrate. The opposite substrate may be a second substrate if the aforementioned substrate is a first substrate.

### Pixel Circuit

An organic light-emitting apparatus having an organic light-emitting device may include a pixel circuit connected to the organic light-emitting device. The pixel circuit may be an active matrix-type circuit that independently controls light emission of a first light-emitting device and a second light-emitting device. The active matrix-type circuit may be a voltage programming or current programming circuit. A driving circuit has a pixel circuit for each pixel. The pixel circuit may have a light-emitting device, a transistor that controls the emission luminance of the light-emitting device, a transistor that controls the timing of light emission, a capacitor that holds the gate voltage of the transistor that controls the emission luminance, and a transistor for establishing the connection to GND without the light-emitting device.

The light-emitting apparatus has a display region and a peripheral region disposed around the display region. The display region includes a pixel circuit, and the peripheral region includes a display control circuit. The mobility of transistors constituting the pixel circuit may be smaller than the mobility of transistors constituting the display control circuit. The slope of the current-voltage characteristics of the transistors constituting the pixel circuit may be smaller than the slope of the current-voltage characteristics of the transistors constituting the display control circuit. The slope of the current-voltage characteristics can be measured by the so-called Vg-Ig characteristics. The transistors constituting the pixel circuit are transistors connected to light-emitting devices including the first light-emitting device.

### Pixel

The organic light-emitting apparatus having an organic light-emitting device may include a plurality of pixels. The pixels each include subpixels that emit light of a color different from the other colors. The subpixels may individually emit, for example, light of colors of RGB.

The pixels each emit light from a region that is also called a pixel aperture. This region is the same as a first region. The pixel aperture may have a size of 15 μm or less and 5 μm or more. More specifically, the pixel aperture may be, for example, 11 μm, 9.5 μm, 7.4 μm, or 6.4 μm. The distance between the subpixels may be 10 μm or less and may be specifically 8 μm, 7.4 μm, or 6.4 μm.

The pixels can have a publicly known arrangement form in plan view. For example, the arrangement form may be the stripe arrangement, the delta arrangement, the PenTile arrangement, or the Bayer arrangement. The subpixels may have any publicly known shape in plan view. For example, the shape may be a quadrangle such as a rectangle or a rhombus, or a hexagon. Of course, figures that are not exactly rectangles but are close to rectangles are also regarded as rectangles. The shape of the subpixels and the pixel arrangement can be used in combination.

### Application of Organic Light-Emitting Device

The organic light-emitting device according to the present embodiment can be used as a constituent member of a display apparatus or an illumination apparatus. In addition, the organic light-emitting device is used in, for example, an exposure light source of an electrophotographic image forming apparatus, a backlight of a liquid crystal display apparatus, and a light-emitting apparatus including a color filter on a white light source.

The display apparatus may be an image information processing apparatus that includes an image input unit to which image information is input from an area CCD, a linear CCD, a memory card, or the like and an information processing unit configured to process the input information, and that displays an input image on a display unit. The display apparatus may include a plurality of pixels, and at least one of the plurality of pixels may include the organic light-emitting device of the present embodiment and an active element, such as a transistor, connected to the organic light-emitting device. In this case, the substrate may be a semiconductor substrate composed of, for example, silicon, and the transistor may be a MOSFET formed on the substrate. An image display apparatus includes an input unit configured to input image information and a display unit configured to output an image, and the display unit includes the display apparatus of the present embodiment.

The display unit included in an imaging apparatus or an ink jet printer may have a touch panel function. The touch panel function may be operated by using infrared radiation, an electrostatic capacitance, a resistive film, or electromagnetic induction, and the operation method is not particularly limited. The display apparatus may be used in a display unit of a multifunctional printer.

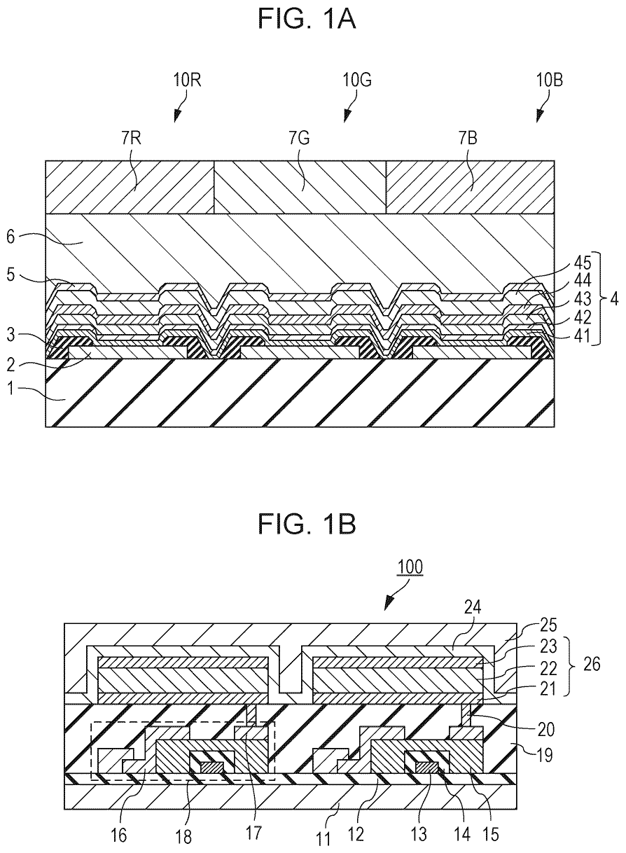

Next, a display apparatus according to the present embodiment will be described with reference to the drawings. FIGS. 1A and 1B are schematic sectional views illustrating an example of a display apparatus including organic light-emitting devices and transistors connected to the organic light-emitting devices. Each of the transistors is one example of an active element. The transistors may be thin-film transistors (TFTs).

FIG. 1A is a schematic sectional view illustrating an example of a pixel that is a component of the display apparatus according to the present embodiment. The pixel has subpixels 10. The subpixels are separated into 10R, 10G, and 10B according to their light emission. The emission color may be distinguished on the basis of the wavelength of light emitted from the light-emitting layer, or the light emitted from the subpixels may be selectively transmitted or subjected to color conversion through a color filter or the like. Each of the subpixels 10 includes, on an interlayer insulating layer 1, a reflective electrode which is a first electrode 2, an insulating layer 3 covering ends of the first electrode 2, an organic compound layer 4 covering the first electrode 2 and the insulating layer 3, a transparent electrode which is a second electrode 5, a protective layer 6, and a color filter 7.

The interlayer insulating layer 1 may have transistors and capacitor elements arranged in a layer disposed thereunder or an interior thereof. Each transistor and the first electrode 2 may be electrically connected to each other through a contact hole or the like not illustrated in the drawing.

The insulating layer 3 is also called a bank or a pixel isolation film. The insulating layer 3 covers ends of the first electrode 2 and is disposed so as to surround the first electrode 2. The portion where the insulating layer 3 is not disposed is in contact with the organic compound layer 4 and serves as a light-emitting region.

The organic compound layer 4 includes a hole injection layer 41, a hole transport layer 42, a first light-emitting layer 43, a second light-emitting layer 44, and an electron transport layer 45. In the pixel in FIG. 1A, the light-emitting layer is composed of two layers. Alternatively, the light-emitting layer may be composed of a single layer or three or more layers.

The second electrode 5 may be a transparent electrode, a reflective electrode, or a semi-transparent electrode.

The protective layer 6 reduces the permeation of moisture into the organic compound layer 4. Although the protective layer 6 is illustrated as a single layer in the drawing, the protective layer 6 may be composed of a plurality of layers. Each layer may be an inorganic compound layer or an organic compound layer.

The color filter 7 is separated into 7R, 7G, and 7B according to the colors thereof. The color filter 7 may be formed on a planarization film not illustrated in the drawing. Furthermore, a resin protective layer not illustrated in the drawing may be disposed on the color filter 7. The color filter 7 may be formed on the protective layer 6. Alternatively, the color filter 7 may be formed on an opposite substrate such as a glass substrate and may then be bonded.

A display apparatus 100 illustrated in FIG. 1B includes organic light-emitting devices 26 and TFTs 18, which are one example of transistors. A substrate 11 composed of glass, silicon, or the like and an insulating layer 12 on top of the substrate 11 are provided. On the insulating layer 12, active elements such as TFTs 18 are disposed, and a gate electrode 13, a gate insulating film 14, and a semiconductor layer 15 of each of the active elements are provided. Each of the TFTs 18 includes a drain electrode 16 and a source electrode 17. An insulating film 19 is disposed on top of the TFTs 18. An anode 21 of each of the organic light-emitting devices 26 is connected to the source electrode 17 through a contact hole 20 formed in the insulating film 19.

The form of the electrical connection between the electrodes (anode 21 and cathode 23) included in each organic light-emitting device 26 and the electrodes (source electrode 17 and drain electrode 16) included in the corresponding one of the TFTs 18 is not limited to the form illustrated in FIG. 1B. In other words, any form may be employed as long as one of the anode 21 and the cathode 23 is electrically connected to one of the source electrode 17 and the drain electrode 16 of the TFT 18.

In the display apparatus 100 illustrated in FIG. 1B, an organic compound layer 22 is illustrated as a single layer. Alternatively, the organic compound layer 22 may be composed of a plurality of layers. A first protective layer 24 and a second protective layer 25 for reducing degradation of the organic light-emitting devices 26 are disposed over cathodes 23.

Although transistors are used as the switching elements in the display apparatus 100 illustrated in FIG. 1B, other switching elements, such as metal-insulator-metal (MIM) elements, may be used instead of the transistors.

The transistors used in the display apparatus 100 illustrated in FIG. 1B are not limited to thin-film transistors that have an active layer on an insulating surface of a substrate but may be transistors that use a single-crystal silicon wafer. Examples of the active layer include layers of single-crystal silicon, non-single-crystal silicon such as amorphous silicon and microcrystalline silicon, and non-single-crystal oxide semiconductors such as indium zinc oxide and indium gallium zinc oxide. Thin-film transistors are also referred to as TFT elements.

The transistors included in the display apparatus 100 illustrated in FIG. 1B may be formed inside a substrate such as a Si substrate. The expression “formed inside a substrate” as used herein means that transistors are produced by processing a substrate, such as a Si substrate, itself. In other words, having transistors inside a substrate can also be considered that a substrate and transistors are integrally formed.

In the organic light-emitting device according to the present embodiment, the emission luminance is controlled by the TFTs, which are one example of switching elements, and thus an image can be displayed at respective emission luminance levels by arranging a plurality of organic light-emitting devices in a plane. The switching elements according to the present embodiment are not limited to TFTs and may be transistors formed of low-temperature polysilicon or active-matrix drivers formed on a substrate such as a Si substrate. The expression “on a substrate” can also be referred to as “inside the substrate”. Whether transistors are formed inside a substrate or TFTs are used is selected on the basis of the size of the display unit. For example, when the size is about 0.5 inches, organic light-emitting devices are preferably disposed on a Si substrate.

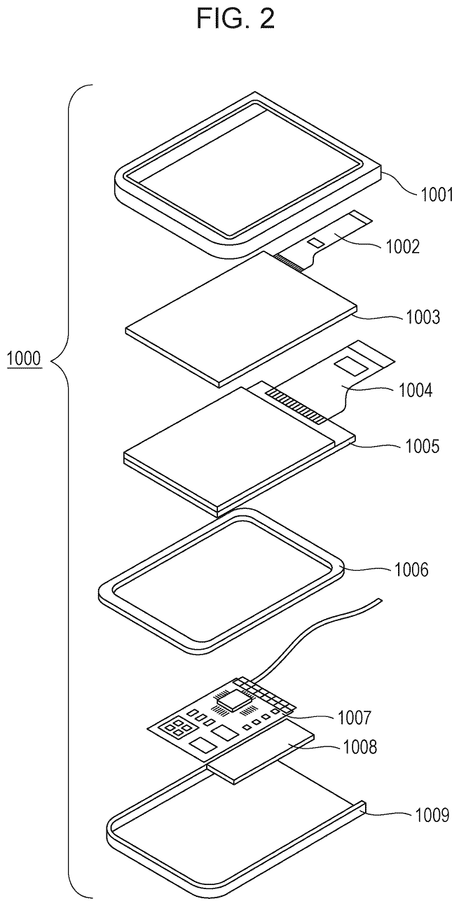

FIG. 2 is a schematic view illustrating an example of a display apparatus according to the present embodiment. A display apparatus 1000 may include an upper cover 1001 and a lower cover 1009, and a touch panel 1003, a display panel 1005, a frame 1006, a circuit board 1007, and a battery 1008 that are disposed between the upper cover 1001 and the lower cover 1009. The touch panel 1003 and the display panel 1005 are connected to flexible printed circuits FPC 1002 and 1004, respectively. Transistors are printed on the circuit board 1007. The battery 1008 is not necessarily installed unless the display apparatus is a portable apparatus or may be installed in a different position even if the display apparatus is a portable apparatus.

The display apparatus according to the present embodiment may include a color filter having red, green, and blue portions. The red, green, and blue portions of the color filter may be arranged in the delta arrangement.

The display apparatus according to the present embodiment may be used in a display unit of a portable terminal. In such a case, the display apparatus may have both a display function and an operation function. Examples of the portable terminal include mobile phones such as smart phones, tablets, and head mount displays.

The display apparatus according to the present embodiment may be used in a display unit of an imaging apparatus including an optical unit including a plurality of lenses and an imaging device configured to receive light that has passed through the optical unit. The imaging apparatus may include a display unit configured to display information acquired by the imaging device. The display unit may be a display unit exposed to the outside of the imaging apparatus or a display unit disposed in a viewfinder. The imaging apparatus may be a digital camera or a digital camcorder.

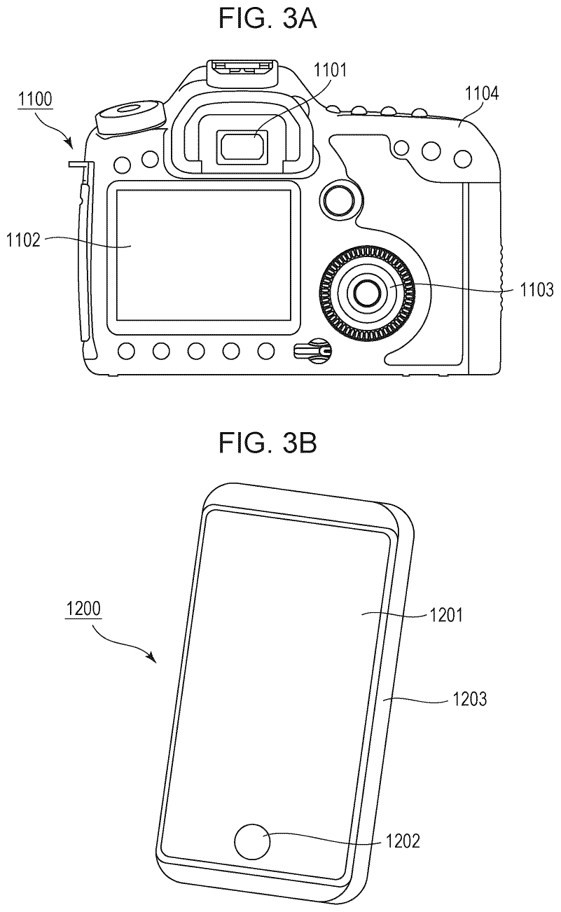

FIG. 3A is a schematic view illustrating an example of an imaging apparatus according to the present embodiment. An imaging apparatus 1100 may include a viewfinder 1101, a rear surface display 1102, an operation unit 1103, and a housing 1104. The viewfinder 1101 may include a display apparatus according to the present embodiment. In such a case, the display apparatus may display not only an image to be captured but also, for example, environmental information and imaging instructions. The environmental information may include, for example, the intensity of external light, the direction of external light, the moving speed of the subject, and the possibility that the subject may hide behind an obstacle.

Since the suitable timing for capturing an image is a very short period of time, it is desirable to display information as quickly as possible. Accordingly, a display apparatus that uses the organic light-emitting device of the present embodiment is preferably used. This is because the organic light-emitting device has a high response speed. The display apparatus that uses the organic light-emitting device can be used more suitably than liquid crystal display apparatuses for such apparatuses required to have a high display speed.

The imaging apparatus 1100 includes an optical unit not illustrated in the drawing. The optical unit includes a plurality of lenses and is configured to form an image on an imaging device contained in the housing 1104. By adjusting the relative positions of the plurality of lenses, the focal point can be adjusted. This operation can also be performed automatically. The imaging apparatus may also be referred to as a photoelectric conversion apparatus. The photoelectric conversion apparatus can employ, instead of a method of successively capturing images, image capturing methods such as a method of detecting a difference from the previous image and a method of extracting images from continuously recorded images.

FIG. 3B is a schematic view of an example of an electronic apparatus according to the present embodiment. An electronic apparatus 1200 includes a display unit 1201, an operation unit 1202, and a housing 1203. The housing 1203 may include therein circuits, a printed circuit board having the circuits, a battery, and a communication unit. The operation unit 1202 may be a button or a touch panel-type responsive unit. The operation unit 1202 may be a biometric authentication unit configured to, for example, recognize the fingerprints and release the lock. The electronic apparatus that includes a communication unit can also be referred to as a communication apparatus. The electronic apparatus 1200 may include a lens and an imaging device so as to further have a camera function. An image captured by the camera function is displayed on the display unit 1201. Examples of the electronic apparatus 1200 include smart phones and notebook computers.

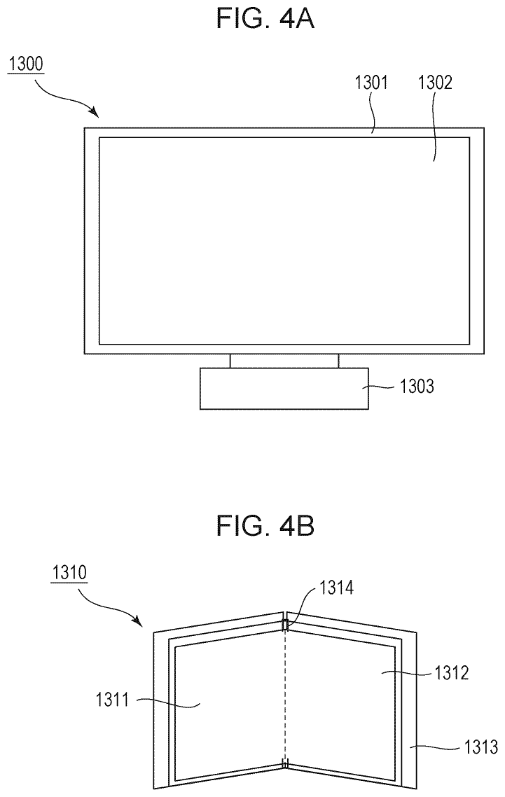

FIGS. 4A and 4B are schematic views each illustrating an example of a display apparatus according to the present embodiment. FIG. 4A illustrates a display apparatus such as a television monitor or a PC monitor. A display apparatus 1300 includes a frame 1301 and a display unit 1302. The light-emitting device according to the present embodiment may be used in the display unit 1302. The display apparatus 1300 includes a base 1303 that supports the frame 1301 and the display unit 1302. The base 1303 is not limited to the form illustrated in FIG. 4A. The lower side of the frame 1301 may also function as the base. The frame 1301 and the display unit 1302 may be curved. The radius of curvature thereof may be 5,000 mm or more and 6,000 mm or less.

FIG. 4B is a schematic view illustrating another example of the display apparatus according to the present embodiment. A display apparatus 1310 illustrated in FIG. 4B is configured to be foldable and is a so-called foldable display apparatus. The display apparatus 1310 has a first display unit 1311, a second display unit 1312, a housing 1313, and a folding point 1314. Each of the first display unit 1311 and the second display unit 1312 may include the light-emitting device according to the present embodiment. The first display unit 1311 and the second display unit 1312 may be a single display apparatus without a joint. The first display unit 1311 and the second display unit 1312 can be separated at the folding point. The first display unit 1311 and the second display unit 1312 may respectively display different images. Alternatively, the first and second display units may collectively display a single image.

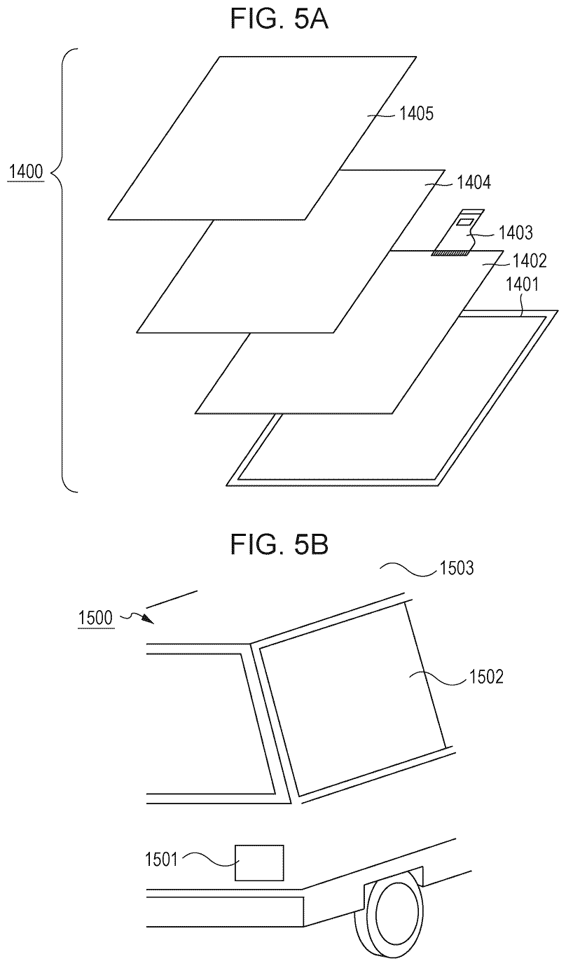

FIG. 5A is a schematic view illustrating an example of an illumination apparatus according to the present embodiment. An illumination apparatus 1400 may include a housing 1401, a light source 1402, a circuit board 1403, an optical filter 1404 and a light diffusion unit 1405 configured to transmit light emitted from the light source 1402. The light source 1402 may include the organic light-emitting device according to the present embodiment. The optical filter 1404 may be a filter that improves the color rendering properties of the light source. The light diffusion unit 1405 can effectively diffuse light emitted from the light source and allow the light to reach a wide range, for example, for lighting up. The optical filter 1404 and the light diffusion unit 1405 may be disposed on the light-emitting side of the illumination. A cover may be optionally disposed on the outermost portion.

The illumination apparatus is, for example, an apparatus that illuminates a room. The illumination apparatus may emit light of a color such as white, natural white, or any other color from blue to red. The illumination apparatus may include a light modulating circuit configured to modulate the light and a color control circuit configured to control the emission color. The illumination apparatus may include the organic light-emitting device according to the present embodiment and a power supply circuit connected to the organic light-emitting device. The power supply circuit is a circuit configured to convert an AC voltage into a DC voltage. The white is a color having a color temperature of 4,200 K, and the natural white is a color having a color temperature of 5,000 K. The illumination apparatus may include a color filter.

The illumination apparatus according to the present embodiment may include a heat dissipation unit. The heat dissipation unit dissipates heat in the apparatus to the outside of the apparatus. The heat dissipation unit may be formed of, for example, a metal having a high specific heat or liquid silicone.

FIG. 5B is a schematic view of an automobile serving as an example of a moving object according to the present embodiment. The automobile has a tail lamp serving as an example of a lighting fixture. An automobile 1500 has a tail lamp 1501, and the tail lamp 1501 may light up when, for example, the brakes are applied.

The tail lamp 1501 may include the organic light-emitting device according to the present embodiment. The tail lamp 1501 may include a protective member that protects the organic light-emitting device. The protective member may be composed of any material that has high strength to a certain extent and is transparent, and is preferably composed of polycarbonate or the like. The polycarbonate may be mixed with a furandicarboxylic acid derivative, an acrylonitrile derivative, or the like.

The automobile 1500 may include a car body 1503 and a window 1502 attached to the car body 1503. The window 1502 may be a transparent display unless it is a window for checking the front and rear of the automobile. The transparent display may include the organic light-emitting device according to the present embodiment. In such a case, the components, such as the electrodes, of the organic light-emitting device are formed of transparent members.

The moving object according to the present embodiment may be, for example, a ship, an aircraft, or a drone. The moving object may include a body and a lighting fixture attached to the body. The lighting fixture may emit light to indicate the position of the body. The lighting fixture includes the organic light-emitting device according to the present embodiment.

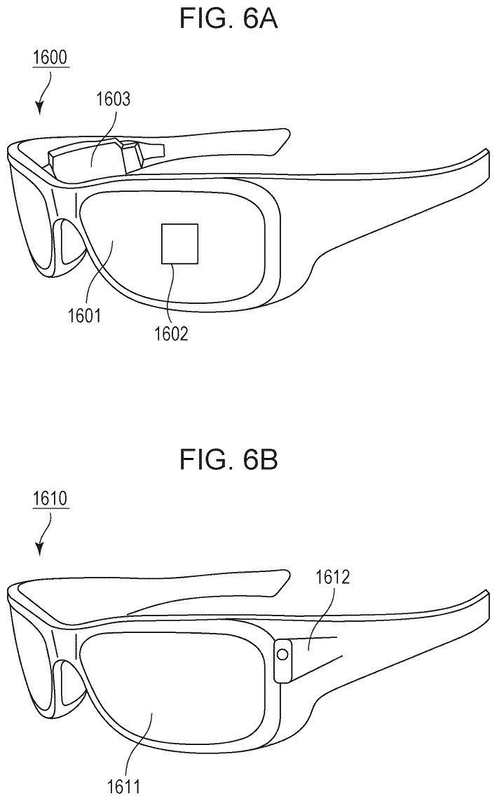

Examples of applications of the display apparatuses according to the embodiments described above will be described with reference to FIGS. 6A and 6B. The display apparatuses are applicable to systems that can be worn as wearable devices, such as smart glasses, head-mounted displays (HMDs), and smart contact lenses. An imaging and display apparatus used in such an example of the application includes an imaging apparatus that can photoelectrically convert visible light and a display apparatus that can emit visible light.

FIG. 6A is a schematic view illustrating an example of a wearable device according to an embodiment of the present disclosure. Glasses 1600 (smart glasses) according to one example of applications will be described with reference to FIG. 6A. An imaging apparatus 1602 such as a complementary metal-oxide semiconductor (CMOS) sensor or a single-photon avalanche diode (SPAD) is disposed on a front side of a lens 1601 of the glasses 1600. The display apparatus according to any of the above-described embodiments is disposed on a back side of the lens 1601.

The glasses 1600 further include a control unit 1603. The control unit 1603 functions as a power supply that supplies electric power to the imaging apparatus 1602 and the display apparatus. The control unit 1603 also controls the operation of the imaging apparatus 1602 and the display apparatus. An optical system for focusing light on the imaging apparatus 1602 is formed in the lens 1601.

FIG. 6B is a schematic view illustrating another example of the wearable device according to an embodiment of the present disclosure. Glasses 1610 (smart glasses) according to one example of applications will be described with reference to FIG. 6B. The glasses 1610 have a control unit 1612. The control unit 1612 includes an imaging apparatus corresponding to the imaging apparatus 1602 in FIG. 6A and a display apparatus. An optical system for projecting light emitted from the display apparatus and the imaging apparatus in the control unit 1612 is formed in a lens 1611, and an image is projected onto the lens 1611. The control unit 1612 functions as a power supply that supplies electric power to the imaging apparatus and the display apparatus and controls the operation of the imaging apparatus and the display apparatus.

The control unit 1612 may have a gaze detection unit that detects the gaze of the wearer. Infrared rays may be used to detect the gaze. An infrared light-emitting unit emits infrared light toward an eyeball of the user who is gazing at a displayed image. An imaging unit including a light-receiving device detects reflection of the emitted infrared light from the eyeball. Thus, a captured image of the eyeball is obtained. The degradation of the image quality is reduced by providing a reducing unit configured to reduce light from the infrared light-emitting unit to a display unit in plan view. The gaze of the user with respect to the displayed image is detected from the captured image of the eyeball captured with the infrared light. Any publicly known method is applicable to the gaze detection using the captured image of the eyeball. As one example, a gaze detection method based on the Purkinje image formed by reflection of irradiation light on the cornea can be employed. More specifically, a gaze detection process based on a pupil-corneal reflection method is performed. The gaze of the user is detected using the pupil-corneal reflection method by calculating a gaze vector that indicates the direction (rotation angle) of the eyeball on the basis of the image of the pupil and the Purkinje image included in the captured image of the eyeball.

The display apparatus according to an embodiment of the present disclosure may include an imaging apparatus including a light-receiving device, and may control a displayed image of the display apparatus on the basis of the gaze information of the user from the imaging apparatus. Specifically, the display apparatus determines a first field-of-view region at which the user gazes and a second field-of-view region other than the first field-of-view region on the basis of the gaze information. The first field-of-view region and the second field-of-view region may be determined by the control unit of the display apparatus or may be determined by receiving those determined by an external control unit. In the display region of the display apparatus, the display resolution of the first field-of-view region may be controlled to be higher than the display resolution of the second field-of-view region. In other words, the resolution of the second field-of-view region may be lower than that of the first field-of-view region.

The display region includes a first display region and a second display region different from the first display region. A region of higher priority is determined from the first display region and the second display region on the basis of the gaze information. The first display region and the second display region may be determined by the control unit of the display apparatus or may be determined by receiving those determined by an external control unit. The resolution of the region of higher priority may be controlled to be higher than the resolution of the region other than the region of higher priority. In other words, the resolution of a region of a relatively low priority may be low.

Artificial intelligence (AI) may be used to determine the first field-of-view region or the region of higher priority. The μl may be a model configured to estimate the angle of the gaze and the distance to a target object at the end of the gaze from the image of the eyeball by using, as teaching data, the image of the eyeball and the direction in which the eyeball in the image was actually gazing. The μl program may be stored in the display apparatus, the imaging apparatus, or an external apparatus. When the AI program is stored in an external apparatus, the AI program is transmitted through communication to the display apparatus.

In the case of controlling the display on the basis of visual recognition detection, the display apparatus according to an embodiment can be preferably applied to smart glasses further including an imaging apparatus that captures an external image. The smart glasses can display the captured external information in real time.

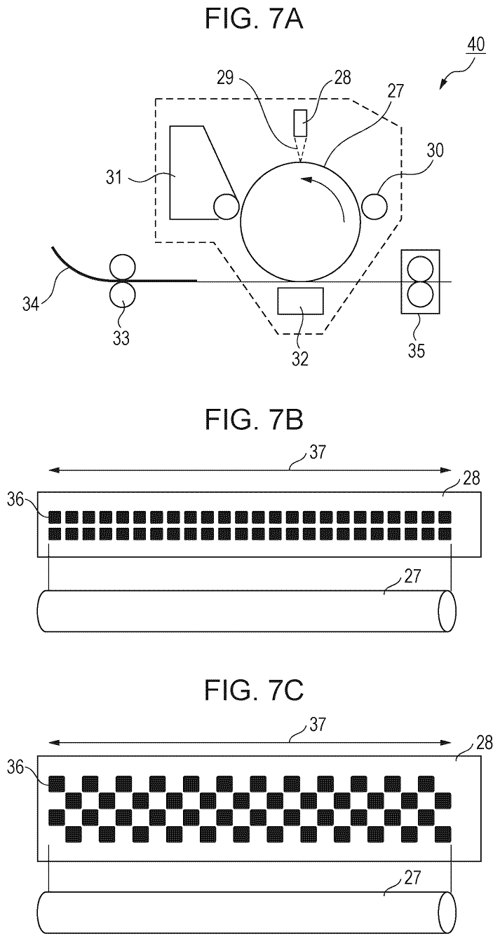

FIG. 7A is a schematic diagram illustrating an example of an image forming apparatus according to an embodiment of the present disclosure. An image forming apparatus 40 is an electrophotographic image forming apparatus and includes a photoreceptor 27, an exposure light source 28, a charging portion 30, a developing portion 31, a transfer unit 32, transport rollers 33, and a fixing unit 35. Light 29 is applied from the exposure light source 28, and an electrostatic latent image is formed on the surface of the photoreceptor 27. The exposure light source 28 includes the organic light-emitting device according to the present embodiment. The developing portion 31 contains a toner and the like. The charging portion 30 charges the photoreceptor 27. The transfer unit 32 transfers a developed image to a recording medium 34. The transport rollers 33 transport the recording medium 34. The recording medium 34 is, for example, paper. The fixing unit 35 fixes the image formed on the recording medium 34.

FIGS. 7B and 7C each illustrate the exposure light source 28 and are each a schematic view illustrating a plurality of light-emitting portions 36 arranged on a long substrate. An arrow 37 indicates a direction parallel to the axis of the photoreceptor, that is, a row direction in which the organic light-emitting devices are arranged. The row direction is the same as the direction of the rotational axis of the photoreceptor 27. This direction can also be referred to as a long-axis direction of the photoreceptor 27. FIG. 7B illustrates a form in which the light-emitting portions 36 are arranged in the long-axis direction of the photoreceptor 27. FIG. 7C illustrates a form which is different from that in FIG. 7B and in which the light-emitting portions 36 are alternately arranged in the row direction in a first row and a second row. The first row and the second row are arranged at different positions in a column direction. In the first row, the plurality of light-emitting portions 36 are arranged at intervals. The second row has the light-emitting portions 36 at positions corresponding to spaces between adjacent ones of the light-emitting portions 36 of the first row. In other words, the plurality of light-emitting portions 36 are also arranged at intervals in the column direction. The arrangement in FIG. 7C can also be referred to as, for example, a lattice arrangement, a staggered arrangement, or a checkered pattern.

As described above, the use of an apparatus using the organic light-emitting device according to the present embodiment enables a stable display for a long time with good image quality. Furthermore, the use of an apparatus using the organic light-emitting device according to the present embodiment enables both good outdoor visibility and power-saving display due to high-efficiency and high-luminance light output.

### Configurations Included

The disclosure of the present embodiment includes the following configurations.

### Configuration 1

An organometallic complex represented by general formula (1), wherein, in general formula (1), M is Pd or Pt; B-A-B is a tetradentate ligand formed by bonding a ring A and rings B together; the ring A is a hydrocarbon aromatic ring or a heteroaromatic ring that may have a substituent, and is selected from a benzene ring, a fluorene ring, a phenanthrene ring, a pyrene ring, a triphenylene ring, a carbazole ring, an N-phenylcarbazole ring, a dibenzofuran ring, a dibenzothiophene ring, a dibenzothiophene 5,5-dioxide ring, a pyridine ring, and a pyrazine ring; the substituent that the ring A may have is selected from a linear or branched alkyl group having 1 to 6 carbon atoms, a fluorine group, a triphenylsilyl group, and a perfluoroalkyl group; each of the rings B is a monocyclic heteroaromatic ring that may have a substituent, and is selected from a pyridine ring, a pyrazine ring, a pyrimidine ring, a pyrrole ring, a pyrazole ring, and a triazole ring; the substituent that the ring B may have is selected from a linear or branched alkyl group having 1 to 6 carbon atoms, a fluorine group, a triphenylsilyl group, a perfluoroalkyl group, an aryl group, and a heteroaryl group; each X—Y is a bidentate ligand, and atoms bonded to M are selected from a C atom, a N atom, and an O atom; and the two bidentate ligands do not bond together.

### Configuration 2

The organometallic complex according to Configuration 1, wherein M is Pt.

### Configuration 3

The organometallic complex according to Configuration 1 or 2, having 2-fold rotational symmetry or mirror symmetry.

### Configuration 4

The organometallic complex according to any one of Configurations 1 to 3, wherein X—Y is any one of bidentate ligands represented by L41 to L50.

### Configuration 5

An organic light-emitting device including a first electrode, a second electrode, and an organic compound layer disposed between the first electrode and the second electrode, wherein the organic compound layer includes a layer containing the organometallic complex according to any one of Configurations 1 to 4.

### Configuration 6

The organic light-emitting device according to Configuration 5, wherein the layer containing the organometallic complex is a light-emitting layer.

### Configuration 7

The organic light-emitting device according to Configuration 6, wherein the organometallic complex is a light-emitting dopant.

### Configuration 8

The organic light-emitting device according to Configuration 6 or 7, further including another light-emitting layer stacked on the light-emitting layer, wherein the other light-emitting layer emits light of a color different from a color of light emitted from the light-emitting layer.

### Configuration 9

The organic light-emitting device according to Configuration 8, wherein the organic light-emitting device emits white light.

### Configuration 10

A display apparatus including a plurality of pixels, wherein at least one of the plurality of pixels includes the organic light-emitting device according to any one of Configurations 5 to 9 and a transistor connected to the organic light-emitting device.

### Configuration 11

An imaging apparatus including an optical unit including a plurality of lenses, an imaging device configured to receive light that has passed through the optical unit, and a display unit configured to display an image captured by the imaging device, wherein the display unit includes the organic light-emitting device according to any one of Configurations 5 to 9.

### Configuration 12

An electronic apparatus including a display unit including the organic light-emitting device according to any one of Configurations 5 to 9, a housing provided with the display unit, and a communication unit provided in the housing and configured to communicate with an external unit.

### Configuration 13

An illumination apparatus including a light source including the organic light-emitting device according to any one of Configurations 5 to 9, and a light diffusion unit or an optical filter configured to transmit light emitted from the light source.

### Configuration 14

A moving object including a lighting fixture including the organic light-emitting device according to any one of Configurations 5 to 9, and a body provided with the lighting fixture.

### Configuration 15

An image forming apparatus including a photoreceptor, and an exposure light source configured to irradiate the photoreceptor with light, wherein the exposure light source includes the organic light-emitting device according any one of Configurations 5 to 9.

### EXAMPLES

Examples will be described below. However, the present disclosure is not limited to these Examples.

### (1) Synthesis Examples

Methods for synthesizing Example compound 01 (Exemplary compound 02), Example compound 02 (Exemplary compound 19), Comparative example compound 01, and Comparative example compound 02 will be described below.

### Method for Synthesizing Example Compound 01 and Comparative Example Compound 01

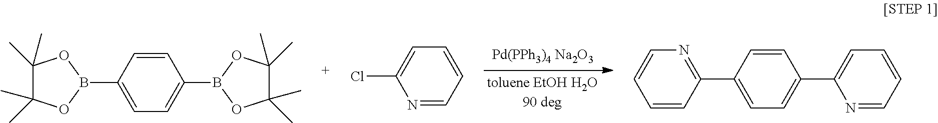

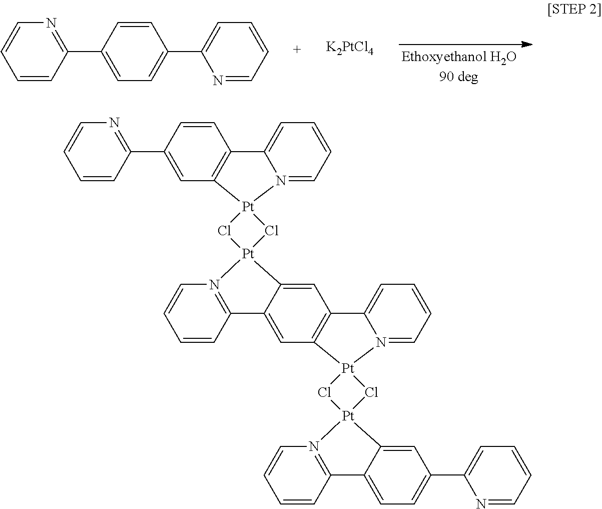

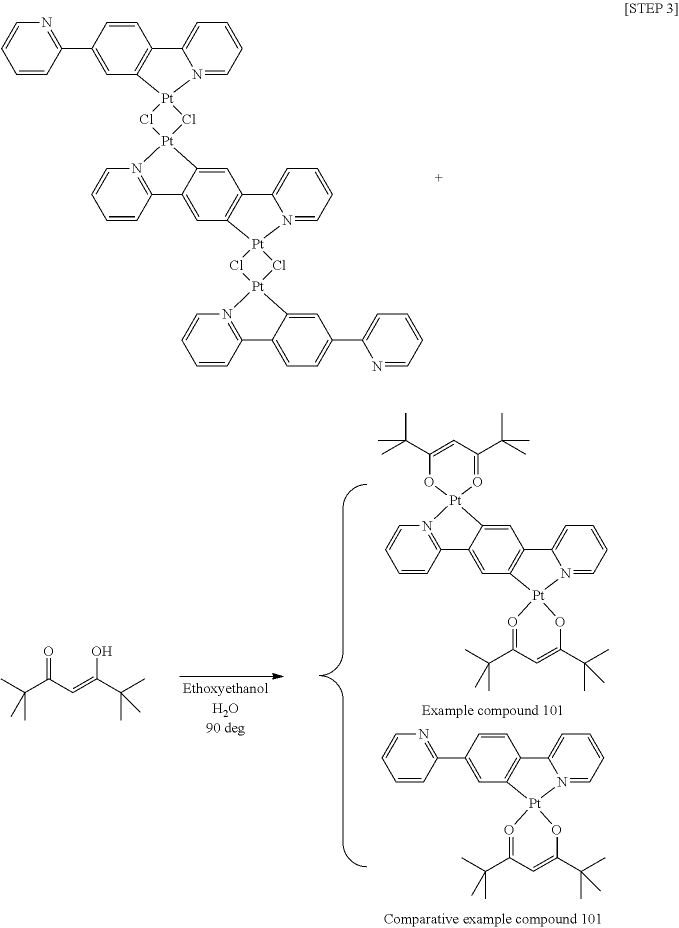

### Step 1: Synthesis of Tetradentate Ligand B-A-B

1,4-Benzenediboronic acid bis(pinacol) ester [3 mmol], 2-chloropyridine [9 mmol], tetrakis(triphenylphosphine)palladium(0) [0.03 mmol], and sodium carbonate, [12 mmol] were added to a mixed solvent (15 mL of toluene, 10 mL of ethanol, and 10 mL of water). The resulting reaction mixture was heated at 90° C. for five hours. The reaction mixture was poured into a separatory funnel, and ethyl acetate and water were used to extract a target reaction product in an organic layer (ethyl acetate). The extraction liquid was filtered through Celite and then concentrated with an evaporator and dried. The reaction product was subjected to silica gel column purification using ethyl acetate as a developing liquid to obtain a ligand 1,4-di(pyridin-2-yl)benzene. The synthesis yield was 90%. The results of the identification by gas chromatogram-mass spectroscopy (GS-MS) showed “m/z=232.1”.

### Step 2: Synthesis of Intermediate of Platinum Complex

To a mixed solvent (7 mL of ethoxyethanol and 3 mL of water), 1,4-di(pyridin-2-yl)benzene [2 mmol] obtained in STEP 1 and K₂PtCl₄ [3 mmol] were added, and the resulting reaction mixture was heated at 90° C. for 10 hours under stirring in a nitrogen stream. A dark red precipitate was filtered and washed with methanol to obtain a dark red powder. For simplicity of description, the reaction scheme shows a tetranuclear complex; however, a hexanuclear or higher polynuclear complex may possibly be generated. The synthesis proceeded to the next synthesis step without identification.

### Step 3: Synthesis of Example Compound 01 and Comparative Example Compound 01

The dark red powder [0.25 mmol (assumed to be a tetranuclear complex)] obtained in STEP 2 and dipivaloylmethane [2 mmol] were added to 10 mL of ethoxyethanol, and the resulting reaction mixture was heated at 90° C. for five hours under stirring in a nitrogen stream. The cooled reaction mixture was added to a separatory funnel, and dichloromethane and water were used to extract a target product in a dichloromethane layer. The extraction liquid was filtered through Celite, dried with magnesium sulfate, and then concentrated with an evaporator to obtain a brown powder. The brown powder was subjected to silica gel column purification using a liquid mixture of ethyl acetate/heptane (6/4) as a developing solvent. A red-light-emitting compound and a yellow-light-emitting compound were separately isolated. The analysis of the compounds revealed that the red-light-emitting compound was Example compound 01 (HPLC purity: 99.0%), and the yellow-light-emitting compound was Comparative example compound 01.

Liquid chromatography-mass spectrometer (LC-MS) and X-ray crystal structure analysis were used for the analysis of the compounds. Crystals for X-ray crystal structure analysis were prepared by using dichloromethane as a good solvent and using methanol as a poor solvent. First, a dichloromethane solution of Example compound 01 was prepared and placed in a test tube, and methanol was slowly added onto the solution to prepare a stacked solution. The resulting solution was left to stand for 10 days to prepare plate-like crystals, and the crystals were used for X-ray analysis.

### Analysis Data of Example Compound 01

The results of LC-MS showed m/z=986.3, and it was confirmed that the target compound was obtained.

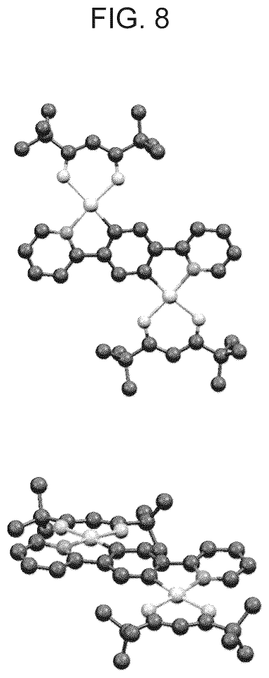

FIG. 8 shows drawn images of X-ray crystallography. The basic data of X-ray crystallography are as follows: unit cell: a=11.9010(4) Å, b=19.4954(6) Å, β=97.071(7)°, c=34.4957(9) Å, Z=8, and space group: P2₁/n. It was confirmed that the structure of the target compound was obtained.

### Method for Synthesizing Example Compound 02 and Comparative Example Compound 02

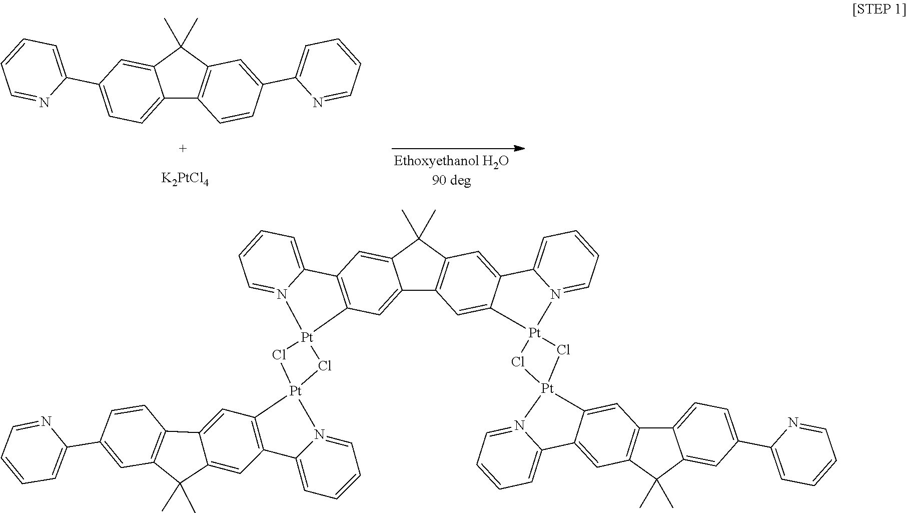

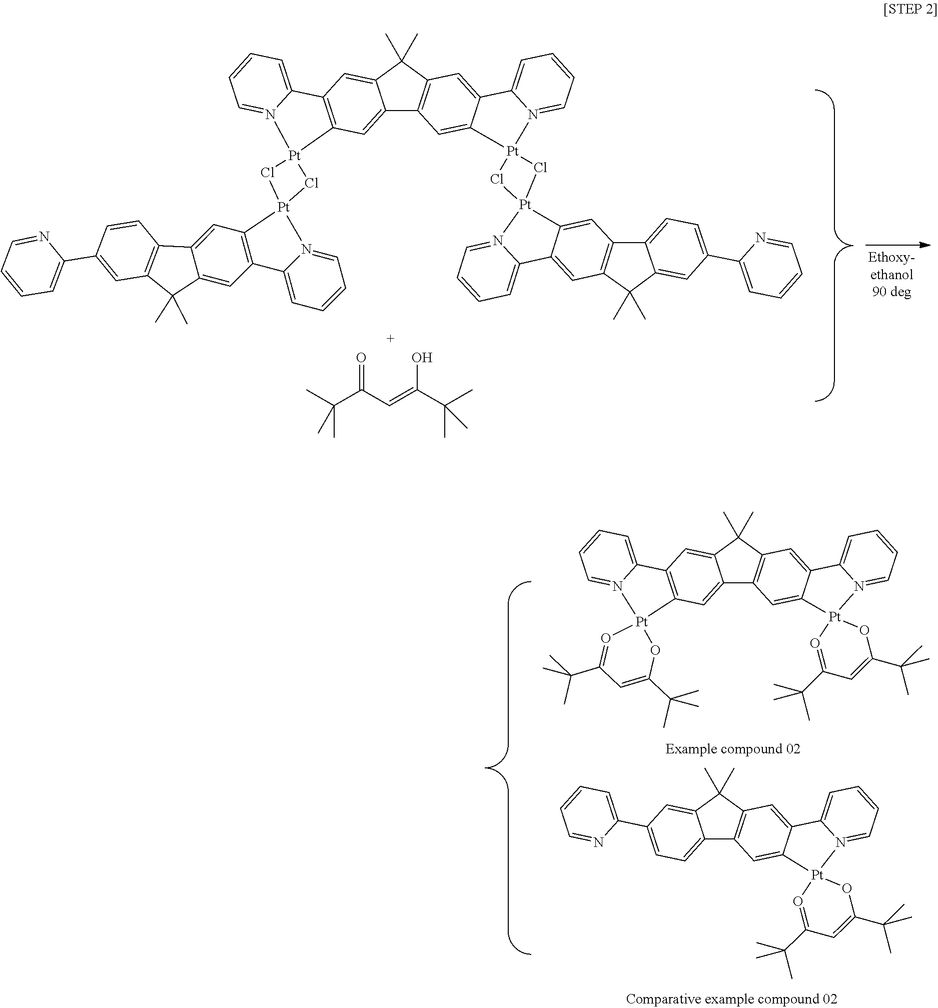

The tetradentate ligand B-A-B was synthesized as in STEP 1 of Example compound 01 using a coupling reaction of corresponding bis(pinacol) borane fluorene with 2-chloropyridine.

### Step 1: Synthesis of Intermediate of Platinum Complex

To a mixed solvent (7 mL of ethoxyethanol and 3 mL of water), 2,2′-(9,9-dimethyl-9H-fluorene-2,7-diyl)dipyridine [2 mmol] obtained above and K₂PtCl₄ [3 mmol] were added, and the resulting reaction mixture was heated at 90° C. for eight hours under stirring in a nitrogen stream. A dark yellow precipitate was filtered and then washed with methanol to obtain a yellow powder. For simplicity of description, the reaction scheme shows a tetranuclear complex; however, a hexanuclear or higher polynuclear complex may possibly be generated. The synthesis proceeded to the next synthesis step without identification.

### Step 2: Synthesis of Example Compound 02 and Comparative Example Compound 02

The yellow powder [0.25 mmol (assumed to be a tetranuclear complex)] obtained in STEP 1 and dipivaloylmethane [2 mmol] were added to 10 mL of ethoxyethanol, and the resulting reaction mixture was heated at 90° C. for eight hours under stirring in a nitrogen stream. The cooled reaction mixture was added to a separatory funnel, and dichloromethane and water were used to extract a target product in a dichloromethane layer. The extraction liquid was filtered through Celite, dried with magnesium sulfate, and then concentrated with an evaporator to obtain a yellow powder. The yellow powder was subjected to silica gel column purification using a liquid mixture of ethyl acetate/heptane (1/1) as a developing solvent. An orange-light-emitting compound and a yellowish-orange-light-emitting compound were obtained and separately isolated. The analysis of the compounds revealed that the orange-light-emitting compound was Example compound 02, and the yellowish-orange-light-emitting compound was Comparative example compound 02.

Liquid chromatography-mass spectrometer (LC-MS) and X-ray crystal structure analysis were used for the identification analysis of the compounds. Crystals for X-ray crystal structure analysis were prepared in the same manner as in Example compound 01.

### Analysis Data of Example Compound 02

The results of LC-MS showed m/z=1102.4, and it was confirmed that the target compound was obtained.

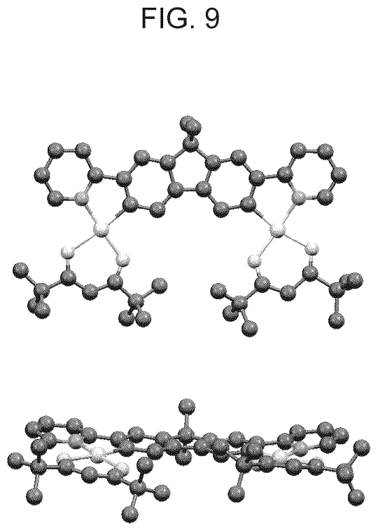

FIG. 9 shows drawn images of X-ray crystallography. The basic data of X-ray crystallography are as follows: unit cell: a=11.8516(5) Å, b=25.0825(11) Å, β=96.303(7)°, c=22.3667(11) Å, Z=6, and space group: Pa. It was confirmed that the structure of the target compound was obtained.

### (2) Performance Evaluation Examples

### Examples 1 and 2 and Comparative Examples 1 to 7

Table 1 shows the results of the comparative evaluation of the performance of the emission characteristics of Example compounds 01 and 02 and Comparative example compounds 01 to 07. FIG. 10 shows PL emission spectra of Example compound 01 and Comparative example compound 01. FIG. 11 shows PL emission spectra of Example compound 02 and Comparative example compound 02.

The measurement was performed under the conditions of a toluene solution (concentration: 10⁻⁵ M) at room temperature. The PL emission spectra were obtained using an F4500 spectrometer manufactured by Hitachi, Ltd., and the photoluminescence quantum yield (PLQY) was determined using an absolute quantum-yield measurement device manufactured by Hamamatsu Photonics K.K.

TABLE 1

| | | Emission peak | FWHM | PLQY |
|---|---|---|---|---|
| | Compound | [nm] | [nm] | [%] |
| Example 1 | Example compound 01 | 618 | 38 | 35 |
| Example 2 | Example compound 02 | 586 | 22 | 31 |
| Comparative Example 1 | Comparative example compound 01 | 529 | 60 | 62 |
| Comparative Example 2 | Comparative example compound 02 | 559 | 65 | 39 |
| Comparative Example 3 | Comparative example compound 03 | 730 | 60 | 0.77 |
| Comparative Example 4 | Comparative example compound 04 | 594 | 100 or more | 11 |
| Comparative Example 5 | Comparative example compound 05 | 609 | 100 or more | 51 |
| Comparative Example 6 | Comparative example compound 06 | 514 | 70 | — |
| Comparative Example 7 | Comparative example compound 07 | 651 | 65 | 4 |

The full widths at half maximum (FWHM) of Example compounds 01 and 02 are 40 nm or less, which are smaller than those of Comparative example compounds 01 to 07 (60 nm to 100 nm or more), thus achieving light emission with high color purity. Relatively high PLQY values (31% to 35%) are also obtained in the solution. The values of PLQY depend on the solvent and the host material. Light-emitting materials that exhibit 30% or more in toluene can be used as light-emitting dopants used in light-emitting layers in organic light-emitting devices.

The results in Table 1 demonstrate that light emission from the metal complexes according to the present disclosure provides a narrow emission spectrum, achieves high color purity, and exhibits a high PLQY.

The present disclosure can provide a binuclear complex that is stable, achieves high efficiency, has a small half-width, and exhibits high color purity. Use of this complex as a light-emitting dopant in a light-emitting layer of an organic EL device can provide a light-emitting device having high efficiency and high color purity.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

1. An organometallic complex represented by general formula (1): 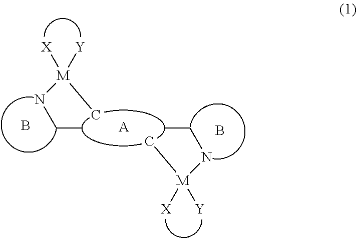
wherein M is Pd or Pt;
B-A-B is a tetradentate ligand formed by bonding a ring A and rings B together;
the ring A is a hydrocarbon aromatic ring or a heteroaromatic ring that may have a substituent, and is selected from a benzene ring, a fluorene ring, a phenanthrene ring, a pyrene ring, a triphenylene ring, a carbazole ring, an N-phenylcarbazole ring, a dibenzofuran ring, a dibenzothiophene ring, a dibenzothiophene 5,5-dioxide ring, a pyridine ring, and a pyrazine ring; the substituent that the ring A may have is selected from a linear or branched alkyl group having 1 to 6 carbon atoms, a fluorine group, a triphenylsilyl group, and a perfluoroalkyl group;
each of the rings B is a monocyclic heteroaromatic ring that may have a substituent, and is selected from a pyridine ring, a pyrazine ring, a pyrimidine ring, a pyrrole ring, a pyrazole ring, and a triazole ring; the substituent that the ring B may have is selected from a linear or branched alkyl group having 1 to 6 carbon atoms, a fluorine group, a triphenylsilyl group, a perfluoroalkyl group, an aryl group, and a heteroaryl group;
each X—Y is a bidentate ligand, and atoms bonded to M are selected from a C atom, a N atom, and an O atom; and
the two bidentate ligands do not bond together.

2. The organometallic complex according to claim 1, wherein M is Pt.

3. The organometallic complex according to claim 1, having 2-fold rotational symmetry or mirror symmetry.

4. The organometallic complex according to claim 1, wherein X—Y is any one of bidentate ligands represented by L41 to L50:

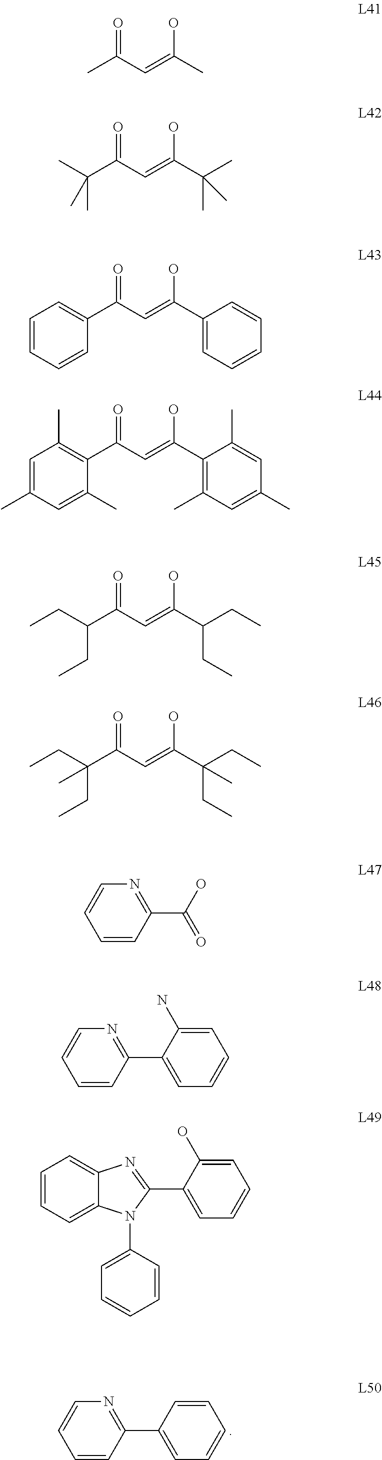

5. An organic light-emitting device comprising:
a first electrode;
a second electrode; and
an organic compound layer disposed between the first electrode and the second electrode,
wherein the organic compound layer includes a layer containing the organometallic complex according to claim 1.

6. The organic light-emitting device according to claim 5, wherein the layer containing the organometallic complex is a light-emitting layer.

7. The organic light-emitting device according to claim 6, wherein the organometallic complex is a light-emitting dopant.

8. The organic light-emitting device according to claim 6, further comprising:
another light-emitting layer stacked on the light-emitting layer,
wherein the other light-emitting layer emits light of a color different from a color of light emitted from the light-emitting layer.

9. The organic light-emitting device according to claim 8, wherein the organic light-emitting device emits white light.

10. A display apparatus comprising:
a plurality of pixels,
wherein at least one of the plurality of pixels includes the organic light-emitting device according to claim 5 and a transistor connected to the organic light-emitting device.

11. An imaging apparatus comprising:
an optical unit including a plurality of lenses;
an imaging device configured to receive light that has passed through the optical unit; and
a display unit configured to display an image captured by the imaging device,
wherein the display unit includes the organic light-emitting device according to claim 5.

12. An electronic apparatus comprising:
a display unit including the organic light-emitting device according to claim 5;
a housing provided with the display unit; and
a communication unit provided in the housing and configured to communicate with an external unit.

13. An illumination apparatus comprising:
a light source including the organic light-emitting device according to claim 5; and
a light diffusion unit or an optical filter configured to transmit light emitted from the light source.

14. A moving object comprising:
a lighting fixture including the organic light-emitting device according to claim 5; and
a body provided with the lighting fixture.

15. An image forming apparatus comprising:
a photoreceptor; and
an exposure light source configured to irradiate the photoreceptor with light,
wherein the exposure light source includes the organic light-emitting device according to claim 5.
